(19) United States
(12) Patent Application Publication
(10) Pub. No.: US 2025/0048864 A1
(43) Pub. Date: Feb. 6, 2025

(54) Display Substrate, Preparation Method thereof, and Display Device

(71) Applicants: Chengdu BOE Optoelectronics Technology Co., Ltd., Chengdu, Sichuan (CN); BOE Technology Group Co., Ltd., Beijing (CN)

(72) Inventors: Changchang LIU, Beijing (CN); Ling SHI, Beijing (CN); Liqiang CHEN, Beijing (CN); Xuewei TIAN, Beijing (CN); Guoyi CUI, Beijing (CN); Yu WU, Beijing (CN)

(21) Appl. No.: 18/688,794

(22) PCT Filed: Sep. 21, 2022
(86) PCT No.: PCT/CN2022/120286

§ 371 Date: Mar. 4, 2024

(51) Int. Cl. H10K 59/131; H10K 59/12; H10K 59/121; H10K 59/80

(52) U.S. Cl. CPC H10K 59/131; H10K 59/1201; H10K 59/1213; H10K 59/1216; H10K 59/873

(57) ABSTRACT

A display substrate and a preparation method thereof, and a display device. The display substrate comprises a display area (100), a bonding area (200), and a side bezel region (310) at least including a first bezel region (310-1) and a second bezel region (310-2), the first bezel region (310-1) is located on a side of the second bezel region (310-2) close to the bonding area (200); the display substrate comprises a base substrate (101) and a drive circuit layer (102), the base substrate (101) at least comprises a first connection line (70), the drive circuit layer (102) at least comprises a data signal line (60), a second connection line (80) connected to the first connection line through a first lap via (DV1), the data signal line is connected to the second connection line through a second lap via (DV2), the first lap via is provided in the first bezel region.

### CROSS-REFERENCE TO RELATED APPLICATION

The present application is a U.S. National Phase Entry of International Application No. PCT/CN2022/120286 having an international filing date of Sep. 21, 2022, the content of which is hereby incorporated by reference.

### TECHNICAL FIELD

The present disclosure relates to, but is not limited to, the field of display technologies, and particularly to a display substrate and a preparation method thereof, and a display device.

### BACKGROUND

An Organic Light Emitting Diode (OLED) and a Quantum dot Light Emitting Diode (QLED) are active light emitting display devices, and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matter described herein in detail. The summary is not intended to limit the scope of protection of the claims.

In one aspect, the present disclosure provides a display substrate, including a display area, a side bezel region located on at least one side of the display area in a first direction, and a bonding area located on a side of the display area in a second direction, wherein the side bezel region at least includes a first bezel region and a second bezel region, the first bezel region is located on a side of the second bezel region close to the bonding area, and the first direction intersects the second direction; the display substrate includes a base substrate and a drive circuit layer provided on the base substrate, the base substrate at least includes a first connection line, the drive circuit layer at least includes a data signal line and a second connection line, the second connection line is connected to the first connection line through a first lap via, the data signal line is connected to the second connection line through a second lap via, and the first lap via is provided in the first bezel region.

In an exemplary embodiment, the display substrate includes a first center line that is a straight line bisecting the display area in the second direction and extending in the first direction, the first bezel region is located on a side of the first center line close to the bonding area, and the first connection line and the second connection line are located on a side of the first center line close to the bonding area.

In an exemplary embodiment, the display substrate includes a second center line that is a straight line bisecting the display area in the first direction and extending in the second direction; distances between a plurality of second lap vias and the second center line are gradually increased in a direction away from the first center line, and distances between the plurality of second lap vias and the first center line are gradually increased in a direction away from the second center line; or, distances between the plurality of second lap vias and the second center line are gradually reduced in a direction away from the first center line, and distances between the plurality of second lap vias and the first center line are gradually reduced in a direction away from the second center line.

In an exemplary embodiment, the bonding area at least includes a lead line, a first end of the lead line is correspondingly connected to an integrated circuit in the bonding area, a second end of the lead line is connected to a first end of the first connection line, a second end of the first connection line is connected to a first end of the second connection line through the first lap via after extending from the bonding area to the first bezel region through the display area, a second end of the second connection line is connected to the data signal line through the second lap via after extending from the first bezel region to the display area.

In an exemplary embodiment, the side bezel region includes an encapsulation region and a non-encapsulation region that are divided by an encapsulation line, wherein the encapsulation line is a boundary of an encapsulation structure layer covering the side bezel region, the encapsulation region is provided on a side of the encapsulation line close to the display area, the non-encapsulation region is provided on a side of the encapsulation line away from the display area, and the first lap via is provided in the non-encapsulation region.

In an exemplary embodiment, the drive circuit layer at least includes a first conductive layer, a second conductive layer and a third conductive layer that are sequentially provided on the base substrate, wherein the second connection line is provided in the first conductive layer or the second conductive layer, and the data signal line is provided in the third conductive layer.

In an exemplary embodiment, the first connection line includes at least a first sub-line and a second sub-line, a first end of the second sub-line is connected to a lead line of the bonding area, a second end of the second sub-line is connected to a first end of the first sub-line after extending to the display area in the second direction, and a second end of the first sub-line is connected to a first end of the second connection line through the first lap via after extending to the first bezel region in the first direction.

In an exemplary embodiment, in the display area, for a first sub-line and the second connection line that transmit the same data signal, an orthographic projection of the first sub-line on the base substrate at least partially overlaps with an orthographic projection of the second connection line on the base substrate.

In an exemplary embodiment, in the second direction, extension lengths of a plurality of second connection lines are gradually increased or extension lengths of the second connection lines are gradually reduced in the second direction.

In an exemplary embodiment, the drive circuit layer includes circuit units constituting a plurality of unit rows and a plurality of unit columns, at least one circuit unit includes a pixel drive circuit, at least one pixel drive circuit includes a storage capacitor and a plurality of transistors, and orthographic projections of the first connection line and the second connection line on the base substrate do not overlap with orthographic projections of the storage capacitor and the plurality of transistors on the base substrate.

In an exemplary embodiment, the display substrate includes a plurality of lead groups, at least one lead group includes k first sub-lines, and k second connection lines correspondingly connected to the k first sub-lines through k first lap vias, the k second connection lines are correspondingly connected to k data signal lines through k second lap vias, and k is a positive integer greater than or equal to 1; and in the display area, at least one lead group is provided between adjacent unit rows.

In an exemplary embodiment, in the second direction, a distance between the i-th lead group and an (i+1)-th lead group is equal to a distance between an (i+1)-th lead group and an (i+2)-th lead group, i is a positive integer greater than or equal to 1, and less than or equal to N−2, and N is a quantity of the lead groups.

In an exemplary embodiment, k is 2, and a spacing between two second lap vias in the i-th lead group is equal to a spacing between two second lap vias in the (i+1)-th lead group.

In an exemplary embodiment, the side bezel region at least includes a gate circuit region, the gate circuit region includes a plurality of gate circuit groups sequentially provided in the second direction, a trace region is provided between adjacent gate circuit groups, and at least one lead group is provided in the trace region in the side bezel region; at least one gate circuit group includes m scan gate circuits sequentially provided in the second direction and n light emitting gate circuits sequentially provided in the second direction, the n light emitting gate circuits are provided on a side of the m scan gate circuits away from the display area, m is a positive integer greater than or equal to 2, and n is a positive integer greater than or equal to 1.

In an exemplary embodiment, at least one scan gate circuit includes a plurality of scan transistors and a scan storage capacitor, at least one light emitting gate circuit includes a plurality of light emitting transistors and a light emitting storage capacitor, and in at least one lead group, orthographic projections of the first sub-line and the second connection line on the base substrate do not overlap with orthographic projections of the scan transistor, the scan storage capacitor, the light emitting transistor and the light emitting storage capacitor on the base substrate.

In an exemplary embodiment, the gate circuit region further includes at least one start signal line and at least one clock signal line that extend in the second direction, and in at least one lead group, orthographic projections of the first sub-line and the second connection line on the base substrate have a first overlapping area with orthographic projections of the start signal line and the clock signal line on the base substrate.

In an exemplary embodiment, in the first overlapping area, an orthographic projection of the first sub-line on the base substrate does not overlap with an orthographic projection of the second connection line on the base substrate.

In an exemplary embodiment, in a side bezel region other than the first overlapping area, for a first sub-line and a second connection line that transmit the same data signal, an orthographic projection of the first sub-line on the base substrate at least partially overlaps with an orthographic projection of the second connection line on the base substrate.

In an exemplary embodiment, at least one first sub-line or at least one second connection line is provided with a resistance compensation structure provided on a side of the gate circuit region away from the display area.

In another aspect, the present disclosure further provides a display device, including the display substrate described above.

In another aspect, the present disclosure further provides a method for preparing a display substrate, wherein the display substrate includes a display area, a side bezel region located on at least one side of the display area in a first direction, and a bonding area located on a side of the display area in a second direction, wherein the side bezel region at least includes a first bezel region and a second bezel region, the first bezel region is located on a side of the second bezel region close to the bonding area, and the first direction intersects the second direction; the method includes: forming a base substrate at least including a first connection line; and forming a drive circuit layer on the base substrate, wherein the drive circuit layer at least includes a data signal line and a second connection line, the second connection line is connected to the first connection line through a first lap via, the data signal line is connected to the second connection line through a second lap via, and the first lap via is provided in the first bezel region.

After the drawings and the detailed descriptions are read and understood, the other aspects may be comprehended.

### BRIEF DESCRIPTION OF DRAWINGS

The accompany drawings are used to provide further understanding of the technical solution of the present disclosure, and form a part of the specification. The accompany drawings and embodiments of the present disclosure are adopted to explain the technical solution of the present disclosure, and do not form limits to the technical solution of the present disclosure.

FIG. 1 is a schematic diagram of a structure of a display device.

FIG. 2 is a schematic diagram of a structure of a display substrate.

FIG. 3 is a schematic diagram of a planar structure of a display area in a display substrate.

FIG. 4 is a schematic diagram of a sectional structure of a display area in a display substrate.

FIG. 5 is a schematic diagram of an equivalent circuit of a pixel drive circuit.

FIG. 6 is a schematic diagram of a planar structure of a display substrate according to an exemplary embodiment of the present disclosure.

FIG. 7 is a schematic diagram of a structure of a first connection line in FIG. 6.

FIG. 8 is a schematic diagram of a structure of a second connection line in FIG. 6.

FIG. 9 is a schematic diagram of a planar structure of another display substrate according to an exemplary embodiment of the present disclosure.

FIG. 10 is a schematic diagram of a planar structure of a still another display substrate according to an exemplary embodiment of the present disclosure.

FIG. 11 is a schematic diagram of a structure of a side bezel region according to an exemplary embodiment of the present disclosure.

FIG. 12 is a schematic diagram of a cross-sectional structure of a lap via according to an exemplary embodiment of the present disclosure.

FIGS. 13A and 13B are schematic diagrams of a planar structure of a data connection line according to an exemplary embodiment of the present disclosure.

FIGS. 14A and 14B are schematic diagrams of a display substrate after a base substrate is formed therein according to an exemplary embodiment of the present disclosure.

FIGS. 15A and 15B are schematic diagrams of a display substrate after a semiconductor layer is formed therein according to an embodiment of the present disclosure.

FIGS. 16A and 16B are schematic diagrams of a display substrate after a first conductive layer is formed therein according to an embodiment of the present disclosure.

FIGS. 17A and 17B are schematic diagrams of a display substrate after a first lap via is formed therein according to an embodiment of the present disclosure.

FIGS. 18A and 18B are schematic diagrams of a display substrate after a second conductive layer is formed therein according to an embodiment of the present disclosure.

FIGS. 19A and 19B are schematic diagrams of a display substrate after a fourth insulating layer is formed therein according to an embodiment of the present disclosure.

FIGS. 20A and 20B are schematic diagrams of a display substrate after a third conductive layer is formed therein according to an embodiment of the present disclosure.

FIG. 21 is a schematic diagram of a structure of a first overlapping area according to an exemplary embodiment of the present disclosure.

FIG. 22 is a schematic diagram of a structure of a resistance compensation structure according to an exemplary embodiment of the present disclosure.

Reference signs are described as follows.

| | | |
|---|---|---|
| 10A-First flexible layer; | 10B-First barrier layer; | 10C-Second flexible layer; |
| 10D-Second barrier layer; | 11-First active layer; | 12-Second active layer; |
| 13-Third active layer; | 14-Fourth active layer; | 15-Fifth active layer; |
| 16-Sixth active layer; | 17-Seventh active layer; | 18-Connection line; |
| 21-First scan signal line; | 22-Second scan signal line | 23-Light emitting control line; |
| 24-First electrode plate; | 31-Initial signal line; | 32-Second electrode plate; |
| 33-Shielding electrode; | 41-First connection electrode; | 42-Second connection |
| | | electrode; |
| 43-Third connection | 44-First power supply line; | 60-Data signal line; |
| electrode; | | |
| 70-First connection line; | 71-First sub-line; | 72-Second sub-line; |
| 73-First connection block; | 80-Second connection line; | 81-Resistance compensation |
| | | structure; |
| 82-Second connection block; | 83-Third connection block; | 90-Lead group; |
| 91-First insulating layer; | 92-Second insulating layer; | 93-Third insulating layer; |
| 94-Fourth insulating layer; | 100-Display area; | 101-Base substrate; |
| 102-Drive circuit layer; | 103-Light emitting structure | 104-Encapsulation structure |
| | layer; | layer; |
| 200-Bonding area; | 201-Lead line region; | 202-Bending region; |
| 220-Lead line; | 300-Bezel area; | 310-Side bezel region; |
| 310A-Encapsulation region; | 310B-Non-encapsulation | 311-Gate circuit region; |
| | region; | |
| 312-Isolation dam region; | 313-Crack dam region; | 314-Cutting region; |
| 320-Upper bezel region; | 330-Scan gate circuit; | 340-Light emitting gate |
| | | circuit; |
| 350-Start signal line; | 351-Light emitting start signal | 352-Scan start signal line; |
| | line; | |
| 360-Clock signal line; | 361-First clock signal line; | 362-Second clock signal line; |
| 410-First isolation dam; | 420-Second isolation dam. | |

### DETAILED DESCRIPTION

To make the objectives, technical solutions, and advantages of the present disclosure clearer, the embodiments of the present disclosure will be described in detail below in combination with the accompany drawings. It is to be noted that the implementations may be implemented in various forms. Those of ordinary skills in the art can easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other in case of no conflicts.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in number but only to avoid the confusion of composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limits to the present disclosure. The positional relationships between the composition elements may be changed as appropriate according to the direction where each composition element is described. Therefore, appropriate replacements based on situations are allowed, not limited to the expressions in the specification.

In the specification, unless otherwise specified and defined, terms “mounting”, “mutual connection”, and “connection” should be generally understood. For example, the connection may be a fixed connection, or detachable connection, or integral connection. The connection may be a mechanical connection or electric connection. The connection may be a direct connection, or indirect connection through an intermediate, or communication inside two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current may flow through the drain electrode, the channel region, and the source region. It is to be noted that in the specification, the channel region refers to a main region that a current flows through.

In the specification, a first electrode may be the drain electrode, and a second electrode may be the source electrode. Alternatively, the first electrode may be a source electrode, and the second electrode may be a drain electrode. In cases that transistors with opposite polarities are used, or a current direction changes during work of a circuit, or the like, functions of the “source electrode” and the “drain electrode” may sometimes be exchanged. Therefore, the “source electrode” and the “drain electrode”, as well as the “source terminal” and the “drain terminal”, are interchangeable in the specification.

In the specification, “electric connection” includes connection of the composition elements through an element with a certain electric action. “An element with a certain electric action” is not particularly limited as long as electric signals between the connected composition elements may be sent and received. Examples of “an element with a certain electric action” not only include an electrode and a line, but also include a switch element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulating film” may be replaced with an “insulating layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc. In the present disclosure, “about” refers to that a boundary is not defined so strictly and numerical values within process and measurement error ranges are allowed.

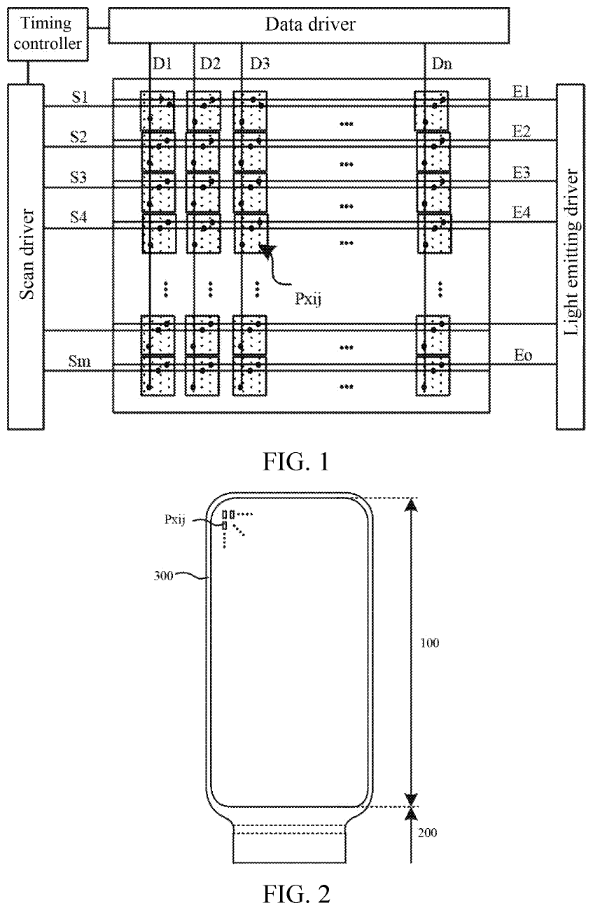

FIG. 1 is a schematic diagram of a structure of a display device. As shown in FIG. 1, the display device may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, wherein both of i and j may be natural numbers. At least one of the sub-pixels Pxij may include a circuit unit and a light emitting unit connected to the circuit unit, wherein the circuit unit may include, at least, a pixel drive circuit that is connected to a scan signal line, a data signal line and a pixel drive circuit, respectively. In an exemplary embodiment, the timing controller may provide a grayscale value and a control signal suitable for the specification of the data signal driver to the data signal driver, may provide a clock signal, a scan start signal, etc. suitable for the specification of the scan driver to the scan driver, and may provide a clock signal, an emission stop signal, etc. suitable for the specification of the light emitting driver to the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a row of pixels as a unit, wherein n may be a natural number. The scan driver may generate scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a structure of a display substrate. As shown in FIG. 2, the display substrate may include a display area 100, a bonding area 200 located on one side of the display area 100, and a bezel area 300 located on other sides of the display area 100. In an exemplary embodiment, the display area 100 may be a planar region including a plurality of sub-pixels Pxij that form a pixel array, the plurality of sub-pixels Pxij are configured to display a dynamic picture or a static image, and the display area 100 may be referred to as an Active Area (AA). In an exemplary embodiment, the display substrate may be deformable, e.g., may be crimped, bent, folded, or curled.

In an exemplary embodiment, a bonding area 200 may include a fan-out region, a bending region, a driver chip region, and a bonding pin region that are disposed sequentially along a direction away from the display area 100. The fan-out region is connected to the display area 100 and may at least include a plurality of data fan-out lines. A plurality of data fan-out lines are configured to be connected to data signal lines of the display area in a fan-out wiring manner. The bending region is connected to the fan-out region and may include a composite insulating layer provided with a groove, and is configured to bend the bonding area to a back of the display area. The driver chip region may include an Integrated Circuit (IC for short) and is configured to be connected to the plurality of data fan-out lines. The bonding pin region may at least include a plurality of bonding pads, and is configured to be bonded to connect to an external Flexible Printed Circuit (FPC for short).

In an exemplary embodiment, the bezel area 300 may include a circuit region, a power supply line region, and a crack dam region and a cutting region which are sequentially provided in a direction away from the display area 100. The circuit region is connected to the display area 100 and may at least include a gate drive circuit which is connected to a first scan signal line, a second scan signal line, and a light emitting control line of a pixel drive circuit in the display area 100. The power supply line region is connected to the circuit region and may at least include a bezel power supply trace that extends along a direction parallel to an edge of the display area and is connected to a cathode in the display area 100. The crack dam region is connected to the power supply line region and may at least include a plurality of cracks arranged on the composite insulating layer. The cutting region is connected to the crack dam region and may at least include a cutting groove arranged on the composite insulating layer, and the cutting groove is configured that a cutting device performs cutting along the cutting groove respectively after preparation of all film layers of the display substrate is completed.

In an exemplary embodiment, the fan-out region in the bonding area 200 and the power supply line region in the bezel area 300 may be at least provided with a first isolation dam and a second isolation dam, the first isolation dam and the second isolation dam may extend in a direction parallel to an edge of the display area, thus forming an annular structure surrounding the display area 100, wherein the edge of the display area is an edge of a side of the display area close to the bonding area or the bezel area.

FIG. 3 is a schematic diagram of a planar structure of a display area in a display substrate. As shown in FIG. 3, the display substrate may include a plurality of pixel units P arranged in a matrix. At least one pixel unit P may include a first sub-pixel P1 emitting light of a first color, a second sub-pixel P2 emitting light of a second color, a third sub-pixel P3 and a fourth sub-pixel P4 which emit light of a third color. Each sub-pixel may include a circuit unit and a light-emitting unit, wherein the circuit unit may at least include a pixel drive circuit connected to a scan signal line, a data signal line, and a light-emitting signal line, respectively, and configured to receive a data voltage transmitted by the data signal line and output a corresponding current to the light-emitting unit under control of the scan signal line and the light-emitting signal line. The light-emitting unit in each sub-pixel is connected to a pixel drive circuit of a sub-pixel where the light-emitting unit is located, and is configured to emit light with a corresponding brightness in response to a current output by the pixel drive circuit connected to the light-emitting unit.

In an exemplary embodiment, the first sub-pixel P1 may be a red sub-pixel (R) emitting red light, the second sub-pixel P2 may be a blue sub-pixel (B) emitting blue light, and the third sub-pixel P3 and the fourth sub-pixel P4 may be green sub-pixels (G) emitting green light. In an exemplary embodiment, a shape of a sub-pixel may be a rectangle, a diamond, a pentagon, or a hexagon. The four sub-pixels may be arranged in a manner of diamond to form an RGBG pixel arrangement. In other exemplary embodiments, the four sub-pixels may be arranged side by side horizontally, side by side vertically, or in a manner to form a square, which is not limited in the present disclosure.

In an exemplary embodiment, a pixel unit may include three sub-pixels, and the three sub-pixels may be arranged side by side horizontally, side by side vertically, or in a manner like a Chinese character “ [symbol] ”, which is not limited here in the present disclosure.

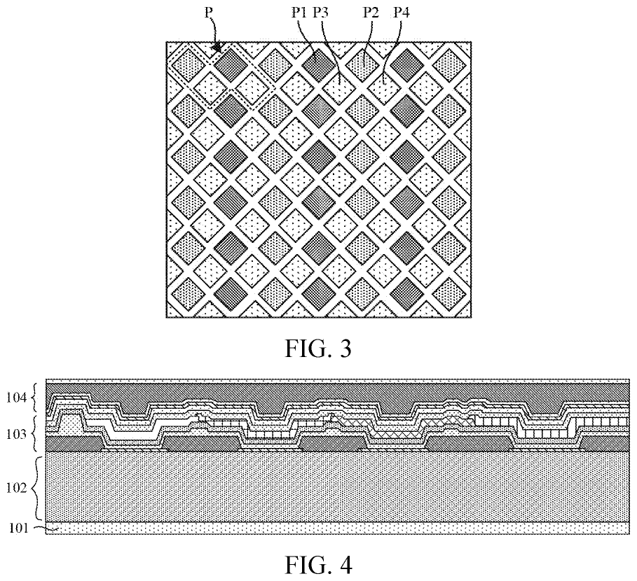

FIG. 4 is a schematic diagram of a sectional structure of a display area in a display substrate, illustrating a structure of four sub-pixels in the display area. As shown in FIG. 4, on a plane perpendicular to the display substrate, the display substrate may include a drive circuit layer 102 arranged on a base substrate 101, a light emitting structure layer 103 arranged on a side of the drive circuit layer 102 away from the base substrate 101, and an encapsulation structure layer 104 arranged on a side of the light emitting structure layer 103 away from the base substrate 101. In some possible implementations, the display substrate may include other film layers, such as a touch structure layer, etc., which is not limited here in the present disclosure.

In an exemplary embodiment, the base substrate 101 may be a flexible base substrate, or may be a rigid base substrate. The drive circuit layer 102 may include a plurality of circuit units, each of which at least includes a pixel drive circuit. The light-emitting structure layer 103 may at least include a plurality of light-emitting units, and each of the light-emitting units at least includes an anode, an organic light-emitting layer and a cathode, wherein the organic light-emitting layer is driven by the anode and the cathode to emit light of a corresponding color. The encapsulation structure layer 104 may include a first encapsulation layer, a second encapsulation layer, and a third encapsulation layer that are stacked, wherein the first encapsulation layer and the third encapsulation layer may be made of an inorganic material, the second encapsulation layer may be made of an organic material, and the second encapsulation layer is provided between the first encapsulation layer and the third encapsulation layer to form an inorganic material/organic material/inorganic material laminated structure and ensure that external water and oxygen cannot enter the light emitting structure layer 103.

In an exemplary embodiment, the organic emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary embodiment, one or more layers of hole injection layers, hole transport layers, electron block layers, hole block layers, electron transport layers, and electron injection layers of all sub-pixels may be a common layer connected together. Emitting layers of adjacent sub-pixels may be overlapped slightly, or may be isolated from each other.

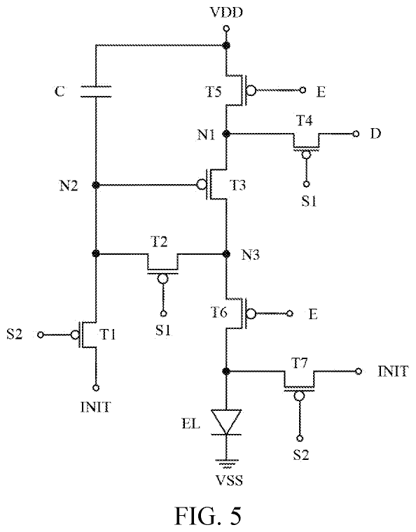

FIG. 5 is a schematic diagram of an equivalent circuit of a pixel drive circuit. In an exemplary embodiment, the pixel drive circuit may have a structure of 3T1C, 4T1C, 5T1C, 5T2C, 6T1C, 7T1C, or 8T1C. As shown in FIG. 5, the pixel drive circuit may include seven transistors (a first transistor T1 to a seventh transistor T7), and one storage capacitor C. The pixel drive circuit is connected to six signal lines (a data signal line D, a first scan signal line S1, a second scan signal line S2, a light-emitting signal line E, an initial signal line INIT, and a first power supply line VDD) respectively.

In an exemplary embodiment, the pixel drive circuit may include a first node N1, a second node N2, and a third node N3. Herein, the first node N1 is respectively connected to a first electrode of the third transistor T3, a second electrode of the fourth transistor T4, and a second electrode of the fifth transistor T5, the second node N2 is respectively connected to a second electrode of the first transistor, a first electrode of the second transistor T2, a gate electrode of the third transistor T3, and a second end of the storage capacitor C, and the third node N3 is respectively connected to a second electrode of the second transistor T2, a second electrode of the third transistor T3, and a first electrode of the sixth transistor T6.

In an exemplary embodiment, a first end of the storage capacitor C is connected to the first power supply line VDD, and a second end of the storage capacitor C is connected to a second node N2, namely the second end of the storage capacitor C is connected to a gate electrode of the third transistor T3.

A gate electrode of the first transistor T1 is connected to the second scan signal line S2, a first electrode of the first transistor T1 is connected to the initial signal line INIT, and a second electrode of the first transistor is connected to the second node N2. When a scan signal with an on-level is applied to the second scan signal line S2, the first transistor T1 transmits an initialization voltage to the gate electrode of the third transistor T3 so as to initialize a charge amount of the gate electrode of the third transistor T3.

A gate electrode of the second transistor T2 is connected to the first scan signal line S1, a first electrode of the second transistor T2 is connected to the second node N2, and a second electrode of the second transistor T2 is connected to a third node N3. When a scan signal with an on-level is applied to the first scan signal line S1, the second transistor T2 enables the gate electrode of the third transistor T3 to be connected to a second electrode of the third transistor T3.

The gate electrode of the third transistor T3 is connected to the second node N2, namely the gate electrode of the third transistor T3 is connected to the second end of the storage capacitor C, a first electrode of the third transistor T3 is connected to a first node N1, and the second electrode of the third transistor T3 is connected to the third node N3. The third transistor T3 may be referred to as a drive transistor, and the third transistor T3 determines an amount of a drive current flowing between the first power supply line VDD and the second power supply line VSS according to a potential difference between the gate electrode and the first electrode of the third transistor T3.

A gate electrode of the fourth transistor T4 is connected to the first scan signal line S1, a first electrode of the fourth transistor T4 is connected to the data signal line D, and a second electrode of the fourth transistor T4 is connected to the first node N1. The fourth transistor T4, may be referred to as a switching transistor, a scan transistor, etc., and the fourth transistor T4 enables a data voltage of the data signal line D to be input into the pixel drive circuit when a scan signal with an on-level is applied to the first scan signal line S1.

A gate electrode of the fifth transistor T5 is connected to the light-emitting signal line E, a first electrode of the fifth transistor T5 is connected to the first power supply line VDD, and a second electrode of the fifth transistor T5 is connected to the first node N1. A gate electrode of the sixth transistor T6 is connected to the light-emitting signal line E, a first electrode of the sixth transistor T6 is connected to the third node N3, and a second electrode of the sixth transistor T6 is connected to a first electrode of the light-emitting unit EL. The fifth transistor T5 and the sixth transistor T6 may be referred to as light emitting transistors. When a light-emitting signal with an on-level is applied to the light-emitting signal line E, the fifth transistor T5 and the sixth transistor T6 enable the light emitting unit EL to emit light by forming a drive current path between the first power supply line VDD and the second power supply line VSS.

A gate electrode of the seventh transistor T7 is connected to the second scan signal line S2, a first electrode of the seventh transistor T7 is connected to the initial signal line INIT, and a second electrode of the seventh transistor T7 is connected to the first electrode of the light-emitting unit EL. When a scan signal with an on-level is applied to the second scan signal line S2, the seventh transistor T7 transmits an initialization voltage to the first electrode of the light-emitting unit EL so as to initialize a charge amount accumulated in the first electrode of the light-emitting unit EL or release a charge amount accumulated in the first electrode of the light-emitting unit EL.

In an exemplary embodiment, the light-emitting unit EL may be an OLED including a first electrode (anode), an organic light emitting layer, and a second electrode (cathode) which are stacked, or may be a QLED including a first electrode (anode), a quantum dot light emitting layer, and a second electrode (cathode) which are stacked.

In an exemplary embodiment, a second electrode of the light-emitting unit EL is connected to the second power supply line VSS, a signal of the second power supply line VSS is a low-level signal continuously provided, and a signal of the first power supply line VDD is a high-level signal continuously provided.

In an exemplary embodiment, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary embodiment, for the first transistor T1 to the seventh transistor T7, low temperature poly silicon thin film transistors may be adopted, or oxide thin film transistors may be adopted, or both a low temperature poly silicon thin film transistor and an oxide thin film transistor may be adopted. An active layer of a low temperature poly silicon thin film transistor may be made of Low Temperature Poly Silicon (LTPS for short), and an active layer of an oxide thin film transistor may be made of an oxide semiconductor (Oxide). The low temperature poly-silicon thin film transistors have advantages such as high migration rate and fast charging, and the oxide thin film transistors have advantages such as low leakage current. The low temperature poly-silicon thin film transistors and the oxide thin film transistors are integrated on one display substrate to form a low temperature polycrystalline oxide (LTPO) display substrate, so that the advantages of both the low temperature poly-silicon thin film transistors and the oxide thin film transistors can be utilized, low-frequency driving can be realized, power consumption can be decreased, and display quality can be improved.

Taking all of the seven transistors being P-type transistors as an example, the operation process of the pixel drive circuit may include the following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is a low-level signals, which causes the first transistor T1 and the seventh transistor T7 to be turned on. The first transistor T1 is turned on such that the initial voltage of the initial signal line INIT is provided to a second node N2 to initialize the storage capacitor C to clear an original data voltage in the storage capacitor. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization. The signals of the first scan signal line S1 and the light emitting signal line E are high-level signals, so that the second transistor T2, the fourth transistor T4, the fifth transistor T5 and the sixth transistor T6 are turned off. An OLED does not emit light in this stage.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the second end of the storage capacitor C is at a low level, so the third transistor T3 is turned on. The signal of the first scan signal line S1 is the low-level signal, so that the second transistor T2 and the fourth transistor T4 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. The signal of the second scan signal line S2 is the high-level signal, so that the first transistor T1 and the seventh transistor T7 are turned off. The signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is a low-level signal, so that the fifth transistor T5 and the sixth transistor T6 are turned on, and a power voltage output by the first power supply line VDD provides a drive voltage to the first electrode of the OLED through the turned-on fifth transistor T5, third transistor T3, and sixth transistor T6 to drive the OLED to emit light.

In a drive process of the pixel drive circuit, a drive current flowing through the third transistor T3 (drive transistor) is determined by a voltage difference between a gate electrode and a first electrode of the third transistor T3. The voltage of the second node N2 is Vdata−|Vth|, so the drive current of the third transistor T3 is as follows.

I=K*(Vgs−Vth)²=K*[(Vdd−Vd+|Vth|)−Vth]²=K*[(Vdd−Vd]²

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

With development of OLED display technologies, consumers have higher requirements for a display effect of a display product. An extremely narrow border has become a new trend in development of display products. Therefore, border narrowing or even a borderless design has attracted more and more attention in a design of an OLED display product. In a display substrate, a data fan-out line is provided in a fan-out region of a bonding area. Since a width of the fan-out region is smaller than that of a display area, the data fan-out line can be introduced into a wider display area through a fan-out tracing manner. The larger the width difference between the display area and the bonding area, the more oblique fan-out lines in a fan-shaped region, and the larger the space occupied by the fan-shaped region. In addition, with gradually increasing resolution of display screens, occupied width of fan-out lines gradually increases, which makes it difficult to narrow a lower bezel, and a width of the lower bezel is about 2.0 mm for a long period.

An exemplary embodiment of the present disclosure provides a display substrate with a structure in which a data connection line is located in a display area (Fanout in AA, abbreviated as FIAA). In an exemplary embodiment, the display substrate may include a display area, a side bezel region located on at least a side of the display area in a first direction, and a bonding area located on a side of the display area in a second direction. The side bezel region at least includes a first bezel region and a second bezel region, the first bezel region is located on a side of the second bezel region close to the bonding area, the first direction intersects the second direction. On a plane perpendicular to the display substrate (i.e. in a thickness direction of the display substrate), the display substrate includes a base substrate and a drive circuit layer provided on the base substrate, the base substrate at least includes a first connection line, the drive circuit layer at least includes a data signal line and a second connection line, the second connection line is connected to the first connection line through a first lap via, the data signal line is connected to the second connection line through a second lap via, and the first lap via is provided in the first bezel region.

In an exemplary embodiment, the first connection line and the second connection line constitute a data connection line, a first end of the data connection line is connected correspondingly to an integrated circuit in the bonding area, and a second end of the data connection line is connected correspondingly to the data signal line after extending to the display area. Since the bonding area does not need to be provided with fan-shaped oblique lines, the width of the fan-out region is reduced, and the width of the lower bezel is effectively reduced.

In an exemplary embodiment, the display substrate may further include an upper bezel region located on a side of the display area away from the bonding area, and the side bezel region and the upper bezel region constitute a bezel area of the display substrate.

In an exemplary embodiment, on a plane perpendicular to the display substrate, the display substrate may further include a light emitting structure layer provided on a side of the drive circuit layer away from the base substrate, and an encapsulation structure layer provided on a side of the light emitting structure layer away from the base substrate. The drive circuit layer may include circuit units forming a plurality of unit rows and a plurality of unit columns, and at least one circuit unit may include a pixel drive circuit configured to output a corresponding current to a light emitting unit connected to the pixel drive circuit. The light emitting structure layer may include a plurality of light emitting units constituting a light emitting array, at least one light emitting unit may include a light emitting device, the light emitting device is connected to a pixel drive circuit of a corresponding circuit unit, and the light emitting device is configured to emit light with a corresponding brightness in response to a current outputted by the connected pixel drive circuit.

In an exemplary embodiment, the circuit units mentioned in the present disclosure refer to regions divided according to pixel drive circuits, and light emitting units mentioned in the present disclosure refer to regions divided according to light emitting devices. In an exemplary embodiment, a position of an orthographic projection of a light emitting unit on the base substrate may correspond to a position of an orthographic projection of a circuit unit on the base substrate, or the position of the orthographic projection of the light emitting unit on the base substrate may not correspond to the position of the orthographic projection of the circuit unit on the base substrate.

In an exemplary embodiment, the display substrate includes a first center line that is a straight line bisecting the display area in the second direction and extending in the first direction, the first bezel region is located on a side of the first center line close to the bonding area, and the first connection line and the second connection line are located on a side of the first center line close to the bonding area.

In an exemplary embodiment, the display substrate includes a second center line that is a straight line bisecting the display area in the first direction and extending in the second direction; in a direction away from the second center line, distances between the second lap vias and the first center line gradually increase, or the distances between the second lap vias and the first centerline gradually decrease.

In an exemplary embodiment, the bonding area at least includes a lead line, a first end of the lead line is correspondingly connected to an integrated circuit in the bonding area, a second end of the lead line is connected to a first end of the first connection line, a second end of the first connection line is connected to a first end of the second connection line through the first lap via after extending from the bonding area to the first bezel region through the display area, and a second end of the second connection line is connected to the data signal line through the second lap via after extending from the first bezel region to the display area.

In an exemplary embodiment, the side bezel region includes an encapsulation region and a non-encapsulation region that are divided by an encapsulation line. The encapsulation line is a boundary of an encapsulation structure layer covering the side bezel region, the encapsulation region is provided on a side of the encapsulation line close to the display area, the non-encapsulation region is provided on a side of the encapsulation line away from the display area, and the first lap via is provided in the non-encapsulation region.

In an exemplary embodiment, the drive circuit layer at least includes a first conductive layer, a second conductive layer and a third conductive layer that are sequentially provided on the base substrate, wherein the second connection line is provided in the first conductive layer or the second conductive layer, and the data signal line is provided in the third conductive layer.

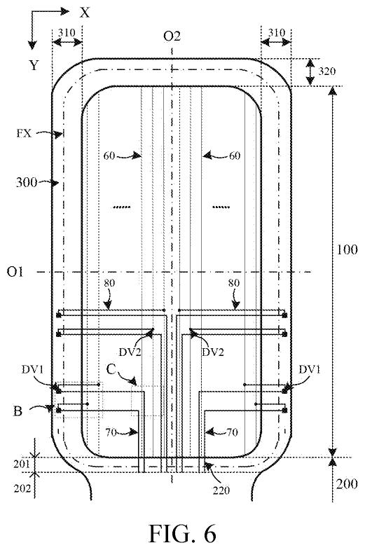

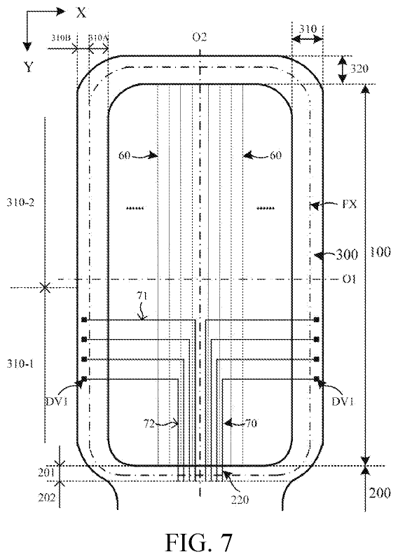

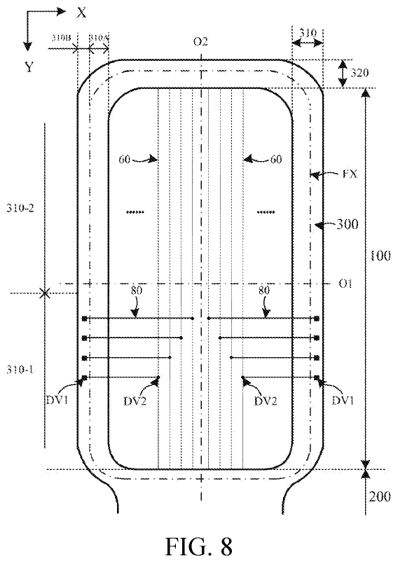

FIG. 6 is a schematic diagram of a planar structure of a display substrate according to an exemplary embodiment of the present disclosure, and data connection lines in the display substrate employ an FIAA structure. FIG. 7 is a schematic diagram of a structure of a first connection line in FIG. 6, and FIG. 8 is a schematic diagram of a structure of a second connection line in FIG. 6. In an exemplary embodiment, on a plane parallel to the display substrate, the display substrate may include a display area 100, a bonding area 200 located on a side of the display area 100 in a second direction Y, and a bezel area 300 located on other sides of the display area 100.

As shown in FIGS. 6 to 8, the display area 100 may at least include a plurality of circuit units forming a plurality of unit rows and a plurality of unit columns, the plurality of circuit units sequentially provided in the first direction X may be referred to as unit rows, the plurality of circuit units sequentially provided in the second direction Y may be referred to as unit columns, the plurality of unit rows and the plurality of unit columns form an array of circuit units arranged in an array, and the first direction X intersects the second direction Y. The display area 100 may further include a plurality of data signal lines 60. A shape of the data signal line 60 may be a line shape in which a main body portion of the data signal line 60 extends in the second direction Y. The plurality of data signal lines 60 are sequentially provided at preset intervals in the first direction X. At least one circuit unit may include a pixel drive circuit, and each data signal line 60 is connected to pixel drive circuits of a plurality of circuit units in one unit column. In an exemplary embodiment, the second direction Y may be an extension direction (vertical direction) of the data signal line 60, and the first direction X may be perpendicular to the second direction Y (horizontal direction).

In the present disclosure, “A extends along a B direction” means that A may include a main portion and a secondary portion connected to the main portion, the main portion is a line, a line segment, or a strip-shaped body, the main portion extends along the B direction, and a length of the main portion extending along the B direction is greater than a length of the secondary portion extending along another direction. In the following description, “A extends in a B direction” means “a main body portion of A extends in a B direction”. In an exemplary embodiment, the second direction Y may be a direction pointing to the bonding area from the display area, and an opposite direction of the second direction Y may be a direction pointing to the display area from the bonding area.

In an exemplary embodiment, the bonding area 200 may at least include a lead line region 201 and a bending region 202 sequentially provided in a direction away from the display area 100, wherein the lead line region 201 may include a plurality of lead lines 220, a first end of the lead line 220 is connected to an integrated circuit in the bonding area 200, and a second end of the lead line 220 extends to the lead line region 201 through the bending region 202.

In an exemplary embodiment, the bezel area 300 may include a side bezel region 310 located on one or both sides of the display area 100 in the first direction X, and an upper bezel region 320 located on a side of the display area 100 away from the bonding area 200, wherein the side bezel region 310 may at least include a gate drive circuit, and the upper bezel region 320 may at least include a test circuit.

In an exemplary embodiment, the bezel area 300 may include an encapsulation region and a non-encapsulation region divided by an encapsulation line which may be a boundary of an encapsulation structure layer covering the bezel area 300. The side bezel region 310 may include an encapsulation region 310A and a non-encapsulation region 310B divided by an encapsulation line FX, the encapsulation region 310A is located on a side of the encapsulation line FX close to the display area 100, and the non-encapsulation region 310B is located on a side of the encapsulation line FX away from the display area 100, that is, the non-encapsulation region 310B may be located on a side of the encapsulation region 310A away from the display area 100.

In an exemplary embodiment, the side bezel region 310 may include a first bezel region 310-1 and a second bezel region 310-2 that are sequentially provided in the second direction Y, and the first bezel region 310-1 may be located on a side of the second bezel region 310-2 close to the bonding area 200.

In an exemplary embodiment, the display substrate may further include a plurality of first connection lines 70 and second connection lines 80, and first connection lines 70 and second connection lines 80 constitute data connection lines. First ends of the plurality of first connection lines 70 are correspondingly connected to the plurality of lead lines 220 in the lead line region 201, and second ends of the plurality of first connection lines 70 extend from the lead line region 201 to the display area 100, and are correspondingly connected to first ends of the plurality of second connection lines 80 through the first lap vias DV1 after extending from the display area 100 to the first bezel region 310-1 in the side bezel region 310. Second ends of the plurality of second connection lines 80 are correspondingly connected to the plurality of data signal lines 60 through second lap vias DV2 after extending from the first bezel region 310-1 to the display area 100. Thereby a data connection line structure is formed, and in the data connection line structure, the first lap vias DV1 are provided in the first bezel region 310-1 and the second lap vias DV2 are provided in the display area 100.

In an exemplary embodiment, since the lead line 220 is connected to the integrated circuit in the bonding area 200, a first connection line 70 is connected to the lead line 220, a second connection line 80 is connected to the first connection line 70, and a data signal line 60 is connected to the second connection line 80, so that the data signal line 60 in the display area is connected to the integrated circuit in the bonding area through the second connection line 80, the first connection line 70, and the lead line 220, thus achieving that the integrated circuit provides a data signal to the data signal line 60. Since the bonding area does not need to be provided with a fan-shaped oblique line, a width of a fan-out region is reduced, and a width of a lower bezel can be effectively reduced.

In an exemplary embodiment, a quantity of the data connection lines may be equal to a quantity of the data signal lines, or the quantity of the data connection lines may be less than the quantity of the data signal lines, which is not limited in the present disclosure.

In an exemplary embodiment, a plurality of first lap vias DV1 may be respectively provided in the non-encapsulation region 310B of the side bezel region 310, i.e., the plurality of first lap vias DV1 are respectively provided on a side of the encapsulation line FX away from the display area 100. By providing a plurality of first lap vias in the non-encapsulation region of the bezel area, the present disclosure may avoid the problem of Growing Dark Spot (GDS) caused by the lap vias compared with providing the first lap vias in the display area.

In an exemplary embodiment, a plurality of first lap vias DV1 may further be respectively provided between the encapsulation line FX of the side bezel region 310 and a first isolation dam 410 (or a second isolation dam 420). By providing a plurality of first lap vias in the bezel area, the present disclosure may avoid the problem of Growing Dark Spot (GDS) caused by the lap vias compared with providing the first lap vias in the display area.

In an exemplary embodiment, the display substrate may include a first center line O1 which may be a straight line bisecting the display area 100 in the second direction Y and extending in the first direction X.

In an exemplary embodiment, the first bezel region 310-1 may be located on a side of the first center line O1 close to the bonding area 200, such that the plurality of first lap vias DV1 and the plurality of second lap vias DV2 are all located on the side of the first center line O1 close to the bonding area 200, and the plurality of first connection lines 70 and the plurality of second connection lines 80 are all located on the side of the first center line O1 close to the bonding area 200. By providing the first lap vias, the second lap vias, the first connection lines and the second connection lines on a side close to the bonding area, the present disclosure can effectively reduce the transmission path of the data signal, effectively reduce the load of the data signal, reduce the rising edge/falling edge (Tr/Tf) of the data signal, and facilitate the realization of a narrow bezel with a high refresh frequency, compared with providing the second lap vias in the upper bezel region.

In an exemplary embodiment, the first connection line 70 may include a first sub-line 71 and a second sub-line 72 connected to each other, wherein the first sub-line 71 may have a line shape extending in the first direction X, and the second sub-line 72 may have a line shape extending in the second direction Y. First ends of a plurality of second sub-lines 72 are correspondingly connected to a plurality of lead lines 220 in the lead line region 201, and second ends of a plurality of second sub-lines 72 are correspondingly connected to first ends of a plurality of first sub-lines 71 after extending from the lead line region 201 to the display area 100 in the second direction Y. Second ends of a plurality of first sub-lines 71 are correspondingly connected to first ends of a plurality of second connection lines 80 through a plurality of first lap vias DV1 after extending from the display area 100 to the first bezel region 310-1 in the first direction X. Second ends of a plurality of second connection lines 80 are correspondingly connected to a plurality of data signal lines 60 through a plurality of second lap vias DV2 after extending from the first bezel region 310-1 to the display area 100 in the first direction X. In an exemplary embodiment, the first sub-line 71 may be perpendicular to the data signal line 60, and the second sub-line 72 may be parallel to the data signal line 60.

In an exemplary embodiment, a first extension length of the first sub-line 71 may be less than or equal to 0.5*a width of the display area, a second extension length of the second sub-line 72 may be less than or equal to 0.5*a length of the display area, the first extension length may be a dimension of the first sub-line 71 in the first direction X, the width of the display area may be a dimension of the display area in the first direction X, the second extension length may be a dimension of the second sub-line 72 in the second direction Y, and the length of the display area may be a dimension of the display area in the second direction Y.

In an exemplary embodiment, in the display area 100, for a first sub-line 71 and a second connection line 80 transmitting the same data signal, an orthographic projection of the first sub-line 71 on the base substrate at least partially overlaps with an orthographic projection of the second connection line 80 on the base substrate, thus forming upper and lower stacked traces of the first sub-line 71 and the second connection line 80 to reduce the parasitic capacitance for transmitting the data signal.

In an exemplary embodiment, a second center line O2 may be included, which may be a straight line bisecting the display area 100 in the first direction X and extending in the second direction Y. A plurality of second sub-lines 72 may be provided in an area close to the second center line O2, and an orthographic projection of at least one second sub-line 72 on a display substrate plane does not overlap with an orthographic projection of at least one data signal line 60 on the display substrate plane.

In an exemplary embodiment, extension lengths of the plurality of second sub-lines 72 are gradually reduced in a direction away from the second center line O2, and extension lengths of the plurality of first sub-lines 71 are gradually reduced in a direction away from the first center line O1. In an exemplary embodiment, the extension length refers to a dimension along the extension direction.

In an exemplary embodiment, in the first bezel region 310-1, a plurality of first lap vias DV1 may be sequentially provided in the second direction Y, and the plurality of first lap vias DV1 may be located on a straight line extending in the second direction Y.

In an exemplary embodiment, extension lengths of the plurality of second connection lines 80 may be gradually reduced in a direction away from the first center line O1.

In an exemplary embodiment, in the display area 100, distances between a plurality of second lap vias DV2 and the second center line O2 may be gradually increased in a direction away from the first center line O1, distances between a plurality of second lap vias DV2 and the first center line O1 may be gradually increased in a direction away from the second center line O2, and the second lap vias DV2 arranged obliquely are formed in the display area 100. The second lap vias DV2 are arranged from lower left to upper right in a left side area of the display area 100, and from lower right to upper left in a right side area of the display area 100.

In an exemplary embodiment, on a plane parallel to the display substrate, a shape of the first lap via DV1 and a shape of the second lap via DV2 may include any one or more of the following: a triangle, a rectangle, a pentagon, a hexagon, a circle, and an ellipse.

In an exemplary embodiment, on a plane perpendicular to the display substrate, the display substrate may include a base substrate, and a drive circuit layer disposed on the base substrate. The base substrate may at least include a first connection line 70, the driver circuit layer may at least include a data signal line 60 and a second connection line 80, the first connection line 70 is connected to the second connection line 80 through a first lap via DV1 located in the first bezel region 310-1, and the second connection line 80 is connected to the data signal line 60 through a second lap via DV2 located in the display area 100.

In an exemplary embodiment, the base substrate may at least include a first flexible layer, a second flexible layer, and a base substrate conductive layer (SD0) disposed between the first flexible layer and the second flexible layer, and the first connection line 70 may be provided in the base substrate conductive layer.

In an exemplary embodiment, the at least one pixel drive circuit may include a storage capacitor and a plurality of transistors. The drive circuit layer may at least include a first conductive layer, a second conductive layer, and a third conductive layer sequentially provided in a direction away from the base substrate, a first electrode plate of the storage capacitor may be provided in the first conductive layer (GATE1), a second electrode plate of the storage capacitor may be provided in the second conductive layer (GATE2), and the data signal line 60 may be provided in the third conductive layer (SD1).

In an exemplary embodiment, in the display area 100, an orthographic projection of the first sub-line 71 on the base substrate does not overlap with an orthographic projection of the storage capacitor and a plurality of transistors on the base substrate, an orthographic projection of the second sub-line 72 on the base substrate does not overlap with the orthographic projection of the storage capacitor and the plurality of transistors on the base substrate, and an orthographic projection of the second connection line on the base substrate does not overlap with the orthographic projection of the storage capacitor and the plurality of transistors on the base substrate.

In an exemplary embodiment, the second connection line 80 may be provided in the first conductive layer, the second connection line 80 may be connected to the first connection line 70 through the first lap via DV1, and the data signal line 60 may be connected to the second connection line 80 through the second lap via DV2.

In another exemplary embodiment, the second connection line 80 may be provided in the second conductive layer, the second connection line 80 may be connected to the first connection line 70 through the first lap via DV1, and the data signal line 60 may be connected to the second connection line 80 through the second lap via DV2.

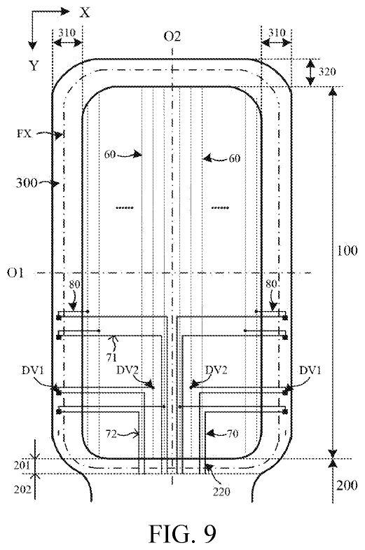

FIG. 9 is a schematic diagram of a planar structure of another display substrate according to an exemplary embodiment of the present disclosure. In an exemplary embodiment, a body structure of the display substrate of the present embodiment is substantially the same as that of the display substrate shown in FIG. 6, except that the plurality of second lap vias DV2 in the display area 100 are arranged differently.

In an exemplary embodiment, extension lengths of a plurality of second sub-lines 72 are gradually reduced in a direction away from the second center line O2, and extension lengths of the plurality of first sub-lines 71 are gradually reduced in a direction away from the first center line O1.

In an exemplary embodiment, extension lengths of the plurality of second connection lines 80 are gradually increased in a direction away from the first center line O1 (i.e., a direction from the first center line O1 to the bonding area).

In an exemplary embodiment, in the display area 100, distances between a plurality of second lap vias DV2 and the second center line O2 may be gradually reduced in a direction away from the first center line O1, distances between a plurality of second lap vias DV2 and the first center line O1 may be gradually reduced in a direction away from the second center line O2, and the second lap vias DV2 arranged obliquely are formed in the display area 100. The second lap vias DV2 are arranged from upper left to lower right in a left side area of the display area 100, and from upper right to lower left in a right side area of the display area 100.

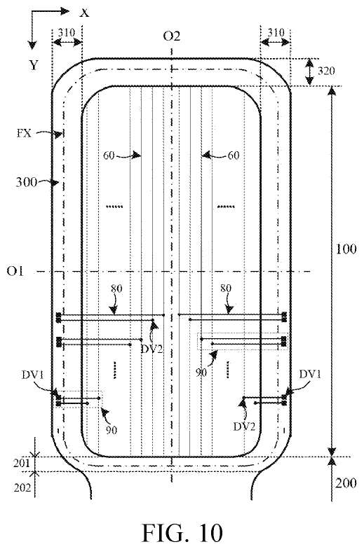

FIG. 10 is a schematic diagram of a planar structure of still another display substrate according to an exemplary embodiment of the present disclosure, only illustrating a structure of a second connection line. In an exemplary embodiment, the display substrate may include a plurality of lead groups 90, and at least one lead group 90 may include k first sub-lines (not shown), and k second connection lines 80 correspondingly connected to the k first sub-lines through k first lap vias DV1, the k second connection lines 80 are correspondingly connected to k data signal lines 60 through k second lap vias DV2, and k is a positive integer greater than or equal to 1. In an exemplary embodiment, a body structure of the display substrate of the present embodiment is substantially the same as that of the display substrate shown in FIG. 6, except that the lead group 90 in the display substrate of FIG. 6 includes one first sub-line and one second connection line, while the lead group 90 in the display substrate of the present embodiment includes two first sub-lines and two second connection lines.

In an exemplary embodiment, in the display area 100, a plurality of lead groups 90 may be sequentially provided in the second direction Y, and each lead group 90 may be provided between adjacent unit rows.

In an exemplary embodiment, two, three or four unit rows may be provided between adjacent lead groups 90 in the second direction Y.

In an exemplary embodiment, in the second direction Y, a distance between the i-th lead group and the (i+1)-th lead group may be equal to a distance between the (i+1)-th lead group and the (i+2)-th lead group, i.e., a plurality of lead groups 90 are arranged at an equal interval in the second direction Y, i is a positive integer greater than or equal to 1, and less than or equal to N−2, and N is a quantity of the lead groups.

In an exemplary embodiment, when k is 1, that is, the lead group 90 as shown in FIG. 6 includes one first sub-line and one second connection line 80, spacings between adjacent first sub-lines are the same, the plurality of first sub-lines are arranged at an equal interval in the second direction Y, spacings between adjacent second connection lines 80 are the same, the plurality of second connection lines 80 are arranged at an equal interval in the second direction Y, spacings between adjacent first lap vias DV1 are the same, the plurality of first lap vias DV1 are arranged at an equal interval in the second direction Y, spacings between adjacent second lap vias DV2 are the same, the plurality of second lap vias DV2 are arranged at an equal interval in an oblique direction, and the plurality of second lap vias DV2 may be located on the same straight line extending in the oblique direction.

In an exemplary embodiment, when k is 1, a difference of extension lengths of the j-th first sub-line and the (j+1)-th first sub-line may be equal to a difference of extension lengths of the (j+1)-th first sub-line and the (j+2)-th first sub-line, that is, the extension lengths of the plurality of first sub-lines are equal differential series, and j is a positive integer greater than or equal to 1 and less than or equal to N−2.

In an exemplary embodiment, when k is 1, a difference of extension lengths of the j-th second connection line 80 and the (j+1)-th second connection line 80 may be equal to a difference of extension lengths of the (j+1)-th second connection line 80 and the (j+2)-th second connection line 80, that is, the extension lengths of the plurality of second connection lines 80 are equal differential series.

In an exemplary embodiment, when k is 1, a difference of extension lengths of the first sub-line and the second connection line 80 in the i-th lead group may be equal to a difference of extension lengths of the first sub-line and the second connection line 80 in the (i+1)-th lead group.

In an exemplary embodiment, when k is 2, that is, the lead group 90 as shown in FIG. 10 includes two first sub-lines and two second connection lines 80, a spacing between two first sub-lines in the i-th lead group may be equal to a spacing between two first sub-lines in the (i+1)-th lead group, a spacing between two second connection lines 80 in the i-th lead group may be equal to a spacing between two second connection lines 80 in the (i+1)-th lead group, a spacing between two first lap vias DV1 in the i-th lead group may be equal to a spacing between two first lap vias DV1 in the (i+1)-th lead group, a spacing between two second lap vias DV2 in the i-th lead group may be equal to a spacing between two second lap vias DV2 in the (i+1)-th lead group, the plurality of second lap vias DV2 are arranged at variable spacings in an oblique direction, and the plurality of second lap vias DV2 are not on the same straight line extending in the oblique direction.

In an exemplary embodiment, when k is 2, a difference of extension lengths of the two first sub-lines in the i-th lead group may be equal to a difference of extension lengths of the two first sub-lines in the (i+1)-th lead group.

In an exemplary embodiment, when k is 2, a difference of extension lengths of the two second connection lines 80 in the i-th lead group may be equal to a difference of extension lengths of the two second connection lines 80 in the (i+1)-th lead group.

In an exemplary embodiment, when k is 2, a difference of extension lengths of the j first sub-line and the (j+1)-th first sub-line may be equal to a difference of extension lengths of the (j+1)-th first sub-line and the (j+2)-th first sub-line, that is, the extension lengths of the plurality of first sub-lines are equal differential series.

In an exemplary embodiment, when k is 2, a difference of extension lengths of the j-th second connection line 80 and the (j+1)-th second connection line 80 may be equal to a difference of extension lengths between the (j+1)-th second connection line 80 and the (j+2)-th second connection line 80, that is, the extension lengths of the plurality of second connection lines 80 are equal differential series.

In an exemplary embodiment, when k is 2, a spacing between the j-th first sub-line and the (j+1)-th first sub-line is not equal to a spacing between the (j+1)-th first sub-line and the (j+2)-th first sub-line, and a spacing between the j-th second connection line 80 and the (j+1)-th second connection line 80 is not equal to a spacing between the (j+1)-th second connection line 80 and the (j+2)-th second connection line 80.

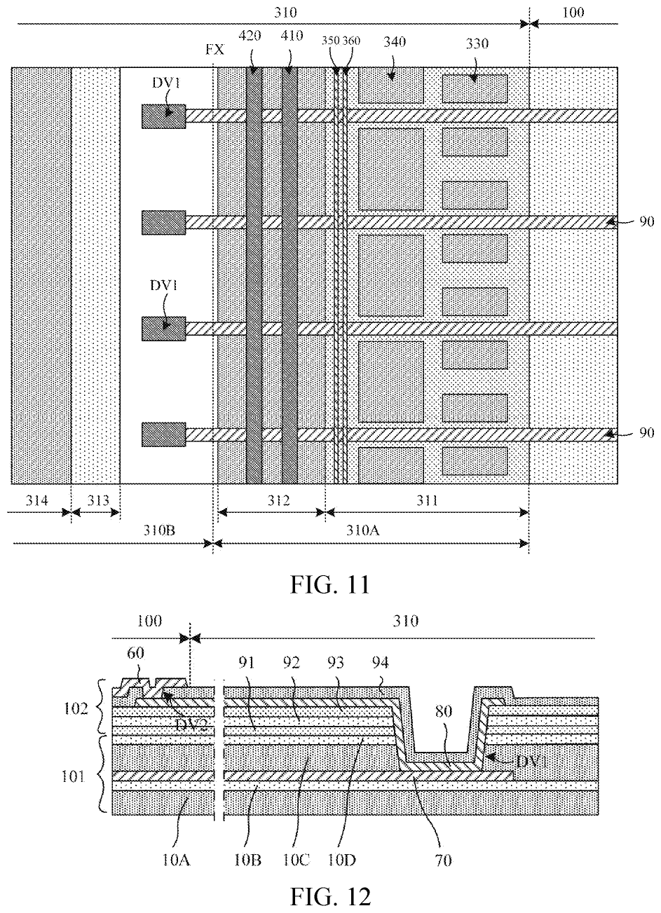

FIG. 11 is a schematic diagram of a structure of a side bezel region according to an exemplary embodiment of the present disclosure. As shown in FIGS. 6 and 11, on a plane parallel to the display substrate, a side bezel region 310 of the bezel area 300 may be located at one side or two sides of the display area 100 in the first direction X, and the side bezel region 310 may include an encapsulation region 310A and a non-encapsulation region 310B that are divided by an encapsulation line FX, and the encapsulation line FX may be a boundary of an encapsulation structure layer covering the side bezel region 310. The encapsulation region 310A is located on a side of the encapsulation line FX close to the display area 100, and the non-encapsulation region 310B is located on a side of the encapsulation line FX away from the display area 100.

In an exemplary embodiment, the encapsulation region 310A may at least include a gate circuit region 311 and an isolation dam region 312 sequentially provided in a direction away from the display area. The gate circuit region 311 may be provided with a plurality of gate circuit groups sequentially provided in the second direction Y, and a trace region is provided between adjacent gate circuit groups in the second direction Y, that is, a plurality of gate circuit groups and a plurality of trace regions are alternately provided in the second direction Y, and a plurality of lead groups 90 are respectively provided in the plurality of trace regions.

In an exemplary embodiment, at least one gate circuit group may include m scan gate circuits (Gate GOA) 330 sequentially provided in a direction parallel to an edge of the display area and n light emitting gate circuits (EM GOA) 340 sequentially provided in the direction parallel to the edge of the display area, the n light emitting gate circuits 340 may be provided on a side of the m scan gate circuits 330 away from the display area 100, m may be a positive integer greater than or equal to 2, and n may be a positive integer greater than or equal to 1. For example, a gate circuit group may include two scan gate circuits 330 and one light emitting gate circuit 340, and the lead groups 90 may be provided between every two scan gate circuits 330 and between each of the light emitting gate circuits 340.

In an exemplary embodiment, the scan gate circuit 330 may at least include a plurality of scan transistors and a scan capacitor, the light emitting gate circuit 340 may at least include a plurality of light emitting transistors and a light emitting capacitor, and the scan transistors, the scan capacitor, the light emitting transistors and the light emitting capacitor may be prepared synchronously with the transistors and storage capacitor in the pixel drive circuit of the display area.

In an exemplary embodiment, the isolation dam region 312 may at least be provided with a first isolation dam 410 and a second isolation dam 420, the first isolation dam 410 and the second isolation dam 420 may extend in a direction parallel to the edge of the display area, and are connected to the first isolation dam and the second isolation dam of the bonding area and the upper bezel region to form an annular structure surround the display area. In an exemplary embodiment, the first isolation dam 410 and the second isolation dam 420 may be prepared synchronously with the light emitting structure layer of the display area.

In an exemplary embodiment, the non-encapsulation region 310B may at least include a crack dam region 313 and a cutting region 314 that are sequentially provided in a direction away from the display area. The crack dam region 313 may at least include a plurality of cracks provided on a composite insulating layer to form a crack dam, the crack dam is configured to reduce stress on the display area during cutting and cut off the propagation of cracks towards the display area. The cutting region 314 may be connected to the crack dam region and may include, at least, a cutting groove disposed on the composite insulating layer, and the cutting groove is configured such that a cutting device performs cutting along the cutting groove respectively after all film layers of the display substrate are prepared.

In an exemplary embodiment, a plurality of first lap vias DV1 may be provided in the non-encapsulation region 310B of the side bezel region 310 and may be provided between the isolation dam region 312 and the crack dam region 313.

In an exemplary embodiment, the first sub-lines 71 in the plurality of lead groups 90 extend from the display area 100 to the side bezel region 310 (the first bezel region), and are connected to the second connection lines 80 through the first lap vias DV1 in the non-encapsulation region 310B after sequentially passing through the gate circuit region 311 and the isolation dam region 312, and the second connection lines 80 are connected to the data signal lines through the second lap vias (not shown) after sequentially passing through the isolation dam region 312 and the gate circuit region 311 and back to the display area 100.

In an exemplary embodiment, for a first sub-line 71 and a second connection line 80 transmitting the same data signal, an orthographic projection of the first sub-line 71 on the base substrate at least partially overlaps with an orthographic projection of the second connection line 80 on the base substrate, thus forming upper and lower stacked traces of the first connection line 70 and the second connection line 80 in the side bezel region 310, thereby effectively reducing the parasitic capacitance for transmitting the data signal.

In an exemplary embodiment, without affecting the normal operation of the scan gate circuit and the light emitting gate circuit (i.e., the sizes of various transistors and capacitors in the scan gate circuit and the light emitting gate circuit remain normal), a trace region may be provided between adjacent gate circuit groups in the second direction Y by a layout design, and the lead group 90 may be provided in a region where the trace region is located, so that the first sub-line 71 and the second connection line 80 in the lead group 90 may avoid various transistors and capacitors in the scan gate circuit and the light emitting gate circuit.

Orthographic projections of the first sub-line 71 and the second connection line 80 on the base substrate do not overlap with orthographic projections of the scan transistors and the scan capacitor of the scan gate circuit 330 on the base substrate, and the orthographic projections of the first sub-line 71 and the second connection line 80 on the base substrate do not overlap with orthographic projections of the light emitting transistors and the light emitting capacitor of the light emitting gate circuit 340 on the base substrate, which can prevent the data signal from affecting the electrical characteristics of the scan gate circuit and the light emitting gate circuit, and ensure the working stability and reliability of the scan gate circuit and the light emitting gate circuit.

In an exemplary embodiment, at least one trace region may be provided with one lead group 90, or two lead groups 90, or a plurality of lead groups 90, and one lead group 90 may at least include one first sub-line 71 and one second connection line 80 that transmit the same data signal. For example, at least one trace region may be provided with one first sub-line 71 and one second connection line 80 providing a data signal for one data signal line of one sub-pixel. For another example, for a pixel unit including a red sub-pixel, a blue sub-pixel, and a green sub-pixel, three first sub-lines 71 and three second connection lines 80 may be provided in at least one trace region to provide data signals for three data signal lines of one pixel unit. For another example, for a pixel unit including a red sub-pixel, a blue sub-pixel, a first green sub-pixel, and a second green sub-pixel, four first sub-lines 71 and four second connection lines 80 may be provided in at least one trace region to provide data signals for four data signal lines of one pixel unit.

In an exemplary embodiment, the gate circuit region 311 may further include at least one start signal (STV) line 350 and at least one clock signal (GOA Clock) line 360, and shapes of these signal lines may be in a line shape extending in a direction parallel to an edge of the display area and may be provided on a side of the light emitting gate circuit 340 away from the display area. In an exemplary embodiment, the start signal line 350 may include signal lines transmitting a scan start signal (GSTV) and a light emitting start signal (ESTV), and the clock signal line 360 may include signal lines transmitting a first clock signal (ECK) and a second clock signal (ECB). Of course, the gate circuit region 311 may further include at least one constant level signal line (not shown), such as a second level signal line (VGH) and a first level signal line (VGL).

In an exemplary embodiment, the gate circuit region 311 includes the first gate circuit region and the second gate circuit region, wherein the first gate circuit region includes at least one scan gate circuit 330, a signal line for transmitting a scan start signal (GSTV) and a clock signal line 360, and the clock signal line 360 may include signal lines transmitting a first clock signal (ECK) and a second clock signal (ECB). Of course, the first gate circuit region may further include at least one constant level signal line, such as a second level signal line (VGH) and a first level signal line (VGL). The second gate circuit region includes at least one light emitting gate circuit 340, a signal line transmitting a light emitting start signal (ESTV), and a clock signal line 360, and the clock signal line 360 may include signal lines transmitting a first clock signal (ECK) and a second clock signal (ECB). Of course, the second gate circuit region may further include at least one constant level signal line, such as a second level signal line (VGH) and a first level signal line (VGL). In an exemplary embodiment, the gate circuit region 311 may further include at least one start signal (STV) line 350 and at least one clock signal (GOA Clock) line 360. At least part of the signal lines may be provided between the light emitting gate circuit 340 and the scan gate circuit 330. Of course, the first gate circuit region may further include at least one constant level signal line, such as a second level signal line (VGH) and a first level signal line (VGL), and the at least one constant level signal line may be provided between the light emitting gate circuit 340 and the scan gate circuit 330.

In an exemplary embodiment, since the first sub-line 71 and the second connection line 80 in the lead group 90 are in a line shape laterally extending, and the start signal line 350 and the clock signal line 360 are in a line shape vertically extending, the first sub-line 71 and the second connection line 80 pass below the start signal line 350 and the clock signal line 360, and orthographic projections of the first sub-line 71 and the second connection line 80 on the base substrate have a first overlapping area with orthographic projections of the start signal line 350 and the clock signal line 360 on the base substrate.

In an exemplary embodiment, in the first overlapping area, the orthographic projection of the first sub-line 71 on the base substrate may not overlap with the orthographic projection of the second connection line 80 on the base substrate, while in a side bezel region other than the first overlapping area, for a first sub-line 71 and a second connection line 80 transmitting the same data signal, an orthographic projection of the first sub-line 71 on the base substrate at least partially overlaps with an orthographic projection of the second connection line 80 on the base substrate.

In an exemplary embodiment, in the first overlapping area, the first sub-line 71 and/or the second connection line 80 may avoid each other by bending, such that the first sub-line 71 and the second connection line 80 located in the first overlapping area do not overlap. By arranging that the first sub-line and the second connection line in the first overlapping area do not overlap, the present disclosure can ensure that the start signal line and the clock signal line will not have large climbing due to the first sub-line and the second connection line provided below, thus avoiding a short circuit caused by metal residue at the climbing place, and improving the process quality.

In an exemplary embodiment, on a side of the gate circuit region 311 away from the display area 100, the first sub-line 71 and the second connection line 80 in the lead group 90 may be provided with a resistance compensation structure that is configured to reduce the resistances of the first sub-line 71 and the second connection line 80, and can adjust a resistance difference caused by different connection line lengths in different lead groups 90.

FIG. 12 is a schematic diagram of a cross-sectional structure of a lap via according to an exemplary embodiment of the present disclosure; As shown in FIG. 12, on a plane perpendicular to the display substrate, the display substrate may at least include a drive circuit layer 102 provided on the base substrate 101. In an exemplary embodiment, the base substrate 101 may at least include a first flexible layer 10A, a second flexible layer 10C, and a base substrate conductive layer disposed between the first flexible layer 10A and the second flexible layer 10C, and the base substrate conductive layer may at least include a first connection line 70. The drive circuit layer 102 may at least include a data signal line 60 and a second connection line 80, the second connection line 80 is connected to the first connection line 70 through a first lap via DV1, and the data signal line 60 is connected to the second connection line 80 through a second lap via DV2.

In an exemplary embodiment, the drive circuit layer 102 may at least include a first insulating layer 91, a semiconductor layer, a second insulating layer 92, a first conductive layer, a third insulating layer 93, a second conductive layer, a fourth insulating layer 94 and a third conductive layer stacked in sequence on the base substrate 101. The semiconductor layer may at least include active layers of a plurality of transistors of the pixel drive circuit, the first conductive layer may at least include gate electrodes of the plurality of transistors and a first plate of the storage capacitor, the second conductive layer may at least include the second connection line 80 and a second plate of the storage capacitor, and the third conductive layer may at least include the data signal line 60 and first electrodes and second electrodes of the plurality of transistors.

In an exemplary embodiment, the base substrate 101 may further include a first barrier layer 10B and a second barrier layer 10D. The first barrier layer 10B is provided between the first flexible layer 10A and a base substrate conductive layer, and the second barrier layer 10D is provided on a side of the second flexible layer 10C away from the first flexible layer 10A.

In an exemplary embodiment, the second connection line 80 covers the first connection line 70 exposed from a bottom of the first lap via DV1 and covers a flexible layer and a plurality of inorganic layers exposed from an inner side wall of the first lap via DV1, and the second connection line 80 covers the third insulating layer outside the first lap via DV1.

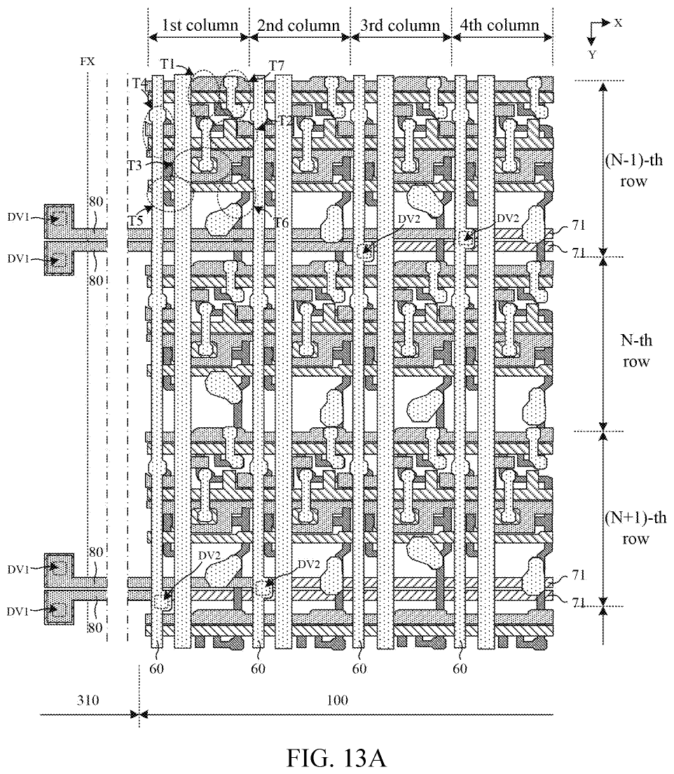

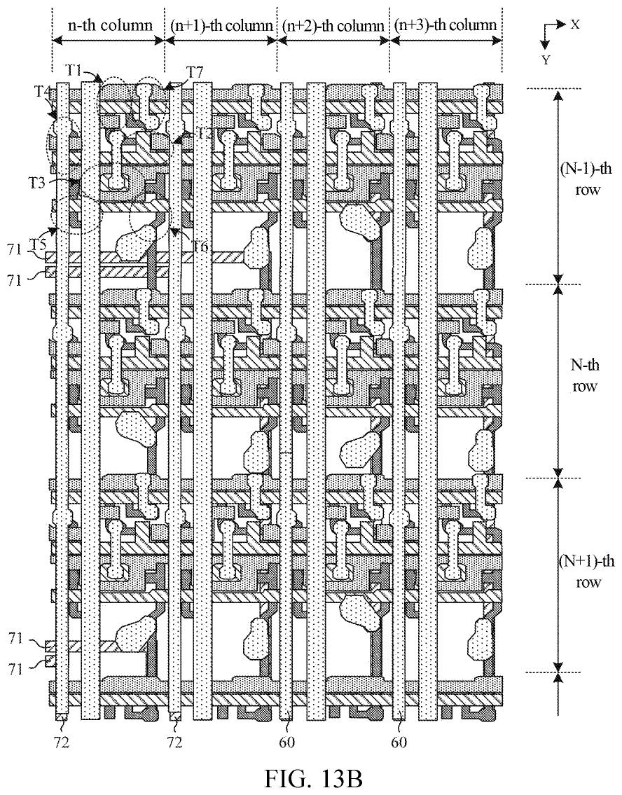

FIGS. 13A and 13B are schematic diagrams of a planar structure of a data connection line according to an exemplary embodiment of the present disclosure, FIG. 13A is a schematic diagram of a planar structure of an area B in FIG. 6, and FIG. 13B is a schematic diagram of a planar structure of an area C in FIG. 6. Each lead group includes two first sub-lines 71 and two second connection lines 80. As shown in FIGS. 13A and 13B, on a plane parallel to the display substrate, the display area 100 may include a plurality of circuit units forming a plurality of unit rows and a plurality of unit columns, at least one circuit unit may include a pixel drive circuit, the pixel drive circuit may at least include a plurality of transistors and a storage capacitor, and a data signal line 60 is connected to a plurality of pixel drive circuits of one unit column, and the data signal line 60 is configured to provide a data signal to the pixel drive circuit.

In an exemplary embodiment, a sub-line group may be provided between adjacent circuit rows, and distances between adjacent sub-line groups in the second direction Y may be substantially equal. For example, one sub-line group may be provided between the (N−1)-th row and the N-th row, another sub-line group may be provided between the (N+1)-th row and the (N+2)-th row, and two circuit rows may be included between adjacent sub-line groups.

In an exemplary embodiment, a distance between two first sub-lines 71 in a sub-line group located between the (N−1)-th row and the N-th row may be equal to a distance between two first sub-lines 71 in a sub-line group located between the (N+1)-th row and the (N+2)-th row, and a distance between two second connection lines 80 in a sub-line group located between the (N−1)-th row and the N-th row may be equal to a distance between two second connection lines 80 in a sub-line group located between the (N+1)-th row and the (N+2)-th row.

In an exemplary embodiment, the second sub-line 72 may be provided in the display area 100, the second sub-line 72 may have a line shape in which the main body portion of the second sub-line 72 extends in the second direction Y, a first end of the second sub-line 72 is connected to a lead line in the bonding area, and a second end of the second sub-line 72 is connected to a first end of the first sub-line 71 after extending from the bonding area to the display area 100.

In an exemplary embodiment, the first sub-line 71 and the second connection line 80 may be provided in the display area 100 and the side bezel region 310, the first lap via DV1 connecting the first sub-line 71 and the second connection line 80 may be provided in the side bezel region 310 (the first bezel region), the first lap via DV1 may be provided on a side of the encapsulation line FX away from the display area 100, and the second lap via DV2 connecting the second connection line 80 and the data signal line 60 may be provided in the display area 100.

In an exemplary embodiment, a distance between two second lap vias DV2 in the sub-line group located between the (N−1)-th row and the N-th row may be equal to a distance between two second lap vias DV2 in the sub-line group located between the (N+1)-th row and the (N+2)-th row.

In an exemplary embodiment, a pixel drive circuit of at least one circuit unit may at least include a first transistor T1, a second transistor T2, a third transistor T3, a fourth transistor T4, a fifth transistor T5, a sixth transistor T6, a seventh transistor T7, and a storage capacitor. Orthographic projections of two first sub-lines 71 and two second connection lines 80 in the lead group on the base substrate do not overlap with orthographic projections of the first transistors T1 to seventh transistors T7 and the storage capacitor on the base substrate, and orthographic projections of two second lap vias DV2 in the lead group on the base substrate do not overlap with orthographic projections of the first transistors T1 to seventh transistors T7 and the storage capacitor on the base substrate.

In an exemplary embodiment, the two first sub-lines 71 and the two second connection lines 80 in the lead group may be located between the fifth transistor T5 and the sixth transistor T6 of the (N−1)-th row and the seventh transistor T7 of the N-th row, and the two second lap vias DV2 in the lead group may be located between the fifth transistor T5 and the sixth transistor T6 of the (N−1)-th row and the seventh transistor T7 of the N-th row.

In an exemplary embodiment, an orthographic projection of the second sub-line 72 on the base substrate does not overlap with orthographic projections of the first electrode plate of the storage capacitor and the second substrate on the base substrate, and the orthographic projection of the second sub-line 72 on the base substrate does not overlap with an orthographic projection of the third transistor T3 on the base substrate.

In an exemplary embodiment, two second sub-lines 72 may be provided in at least one unit column, the two second sub-lines 72 may be respectively located on both sides of the unit column in the first direction X, and an orthographic projection of the at least one second sub-line 72 on the base substrate at least partially overlaps with an orthographic projection of the data signal line 60 on the base substrate.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition. Coating may be any one or more of spray coating, spin coating, and inkjet printing. Etching may be any one or more of wet etching and dry etching. A “thin film” refers to a layer of thin film made of a certain material on a substrate using deposition, coating, or other processes. If the “thin film” does not need to be processed through a patterning process in the entire preparing process, the “thin film” may also be called a “layer”. If the “thin film” needs to be processed through the patterning process in the entire preparing process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a size of the film layer in a direction perpendicular to a display substrate. In an exemplary embodiment of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A is coincided with the boundary of the orthographic projection of B.

In an exemplary embodiment, a preparation process of the display substrate according to the exemplary embodiment may include following operations.

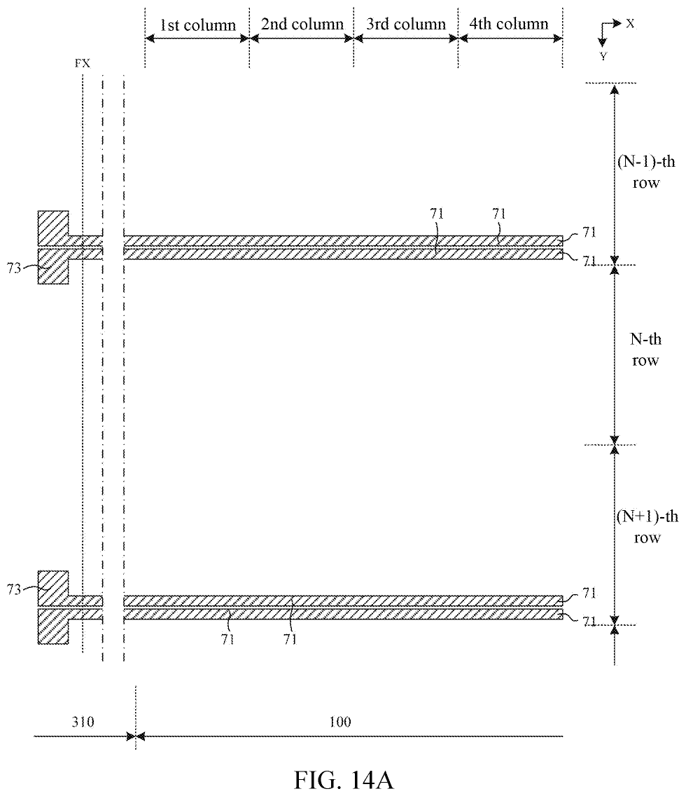

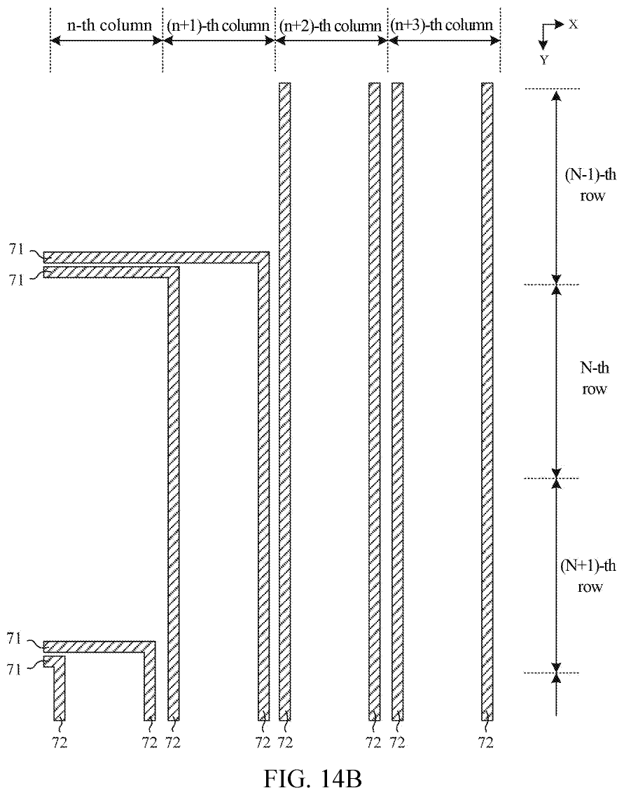

(1) A base substrate is prepared. In an exemplary implementation, preparing the base substrate may include: a layer of a first flexible material is coated on a glass carrier plate at first, after the layer of the first flexible material is cured into a film, a first flexible layer 10A is formed. Then a first barrier thin film and a base substrate conductive film are sequentially deposited on the first flexible layer 10A, and the base substrate conductive film is patterned by a patterning process to form a first barrier layer covering the first flexible layer and a pattern of the base substrate conductive layer provided on the first barrier layer. A layer of a second flexible material is then coated and cured into film to form a second flexible layer covering the pattern of the base substrate conductive layer. Then, a second barrier thin film is deposited to form a second barrier layer covering the second flexible layer, as shown in FIGS. 14A and 14B, wherein FIG. 14A is a schematic diagram of a planar structure of an area B in FIG. 6, and FIG. 14B is a schematic diagram of a planar structure of an area C in FIG. 6. In an exemplary embodiment, the base substrate conductive layer may be referred to as a 0th source and drain metal (SD0) layer.

In an exemplary embodiment, the pattern of the base substrate conductive layer may at least include a plurality of first sub-lines 71 provided in the display area 100 and the side bezel region 310, and a plurality of second sub-lines 72 provided in the display area 100. A shape of the first sub-line 71 may be a line shape in which the main body portion of the first sub-line 71 extends in the first direction X, and a shape of the second sub-line 72 may be a line shape in which the main body portion of the second sub-line 72 extends in the second direction Y. A first end of the second sub-line 72 is connected to the lead line in the bonding area, a second end of the second sub-line 72 is connected to a first end of the first sub-line 71 after extending from the bonding area to the display area 100, and a second end of the first sub-line 71 extends from the display area 100 to the side bezel region 310.

In an exemplary embodiment, an end of the first sub-line 71 away from the display area 100 (the second end of the first sub-line 71) is provided with a first connection block 73, a shape of the first connection block 73 may be a rectangle. The first connection block 73 is connected to the first sub-line 71 and configured to be connected to a second connection line formed subsequently through a first lap via.

In an exemplary embodiment, the first sub-line 71, the second sub-line 72 and the first connection block 73 may be of an integral structure interconnected to each other.

In an exemplary embodiment, the first connection block 73 may be provided on a side of the encapsulation line FX away from the display area, and the plurality of first connection blocks 73 may be located on a straight line extending in the second direction Y.

In an exemplary embodiment, a plurality of second sub-lines 72 may be provided at intervals in the first direction X, two second sub-lines 72 may be provided in at least one unit column, and the two second sub-lines 72 may be respectively located on both sides of the unit column in the first direction X, which is not limited here in the present disclosure.

In an exemplary embodiment, the sub-line group may include two first sub-lines 71, the sub-line group may be provided between adjacent circuit rows, distances between adjacent sub-line groups in the second direction Y may be substantially equal, and two circuit rows may be included between adjacent sub-line groups.

In an exemplary embodiment, a distance between the two first sub-lines 71 in the sub-line group located between the (N−1)-th row and the N-th row may be equal to a distance between the two first sub-lines 71 in the sub-line group located between the (N+1)-th row and the (N+2)-th row.

In an exemplary embodiment, in at least one sub-line group, the first connection block 73 on the first sub-line 71 may be provided on a side of the first sub-line 71 away from the other first sub-line 71, thereby increasing a spacing between the two first lap vias as much as possible to improve the connection reliability.

In an exemplary embodiment, the material of the first flexible layer and the second flexible layer may include, but is not limited to, one or more of polyethylene glycol terephthalate, polyethylene terephthalate, polyether-ether-ketone, polystyrene, polycarbonate, polyarylate, polyarylester, polyimide, polyvinyl chloride, polyethylene, and textile fibers. The material of the first barrier layer and the second barrier layer may include, but is not limited to, one or more of a silicon oxide (SiOx), a silicon nitride (SiNx), and a silicon oxynitride (SiON), which may form a single layer, a multi-layer, or a composite layer for improving the water-oxygen resistance of the base substrate. The base substrate conductive layer may be made of a metal material, such as any one or more of silver (Ag), copper (Cu), aluminum (Al), and molybdenum (Mo), or an alloy material of the aforementioned metals. For example, the base substrate conductive layer may adopt molybdenum.

In an exemplary embodiment, a Titanium/Aluminum/Titanium (Ti/Al/Ti) composite structure may be adopted for the base substrate conductive layer, which is beneficial to reducing the resistance of the first connection line.

In the display substrate according to the exemplary embodiment of the present disclosure, a base substrate conductive layer is provided between the two flexible layers of the base substrate, and the base substrate conductive layer includes a first connection line for implementing a fan-out function in the display area and the bezel area, which is beneficial to reducing the width of the bonding area and achieving a narrow bezel.

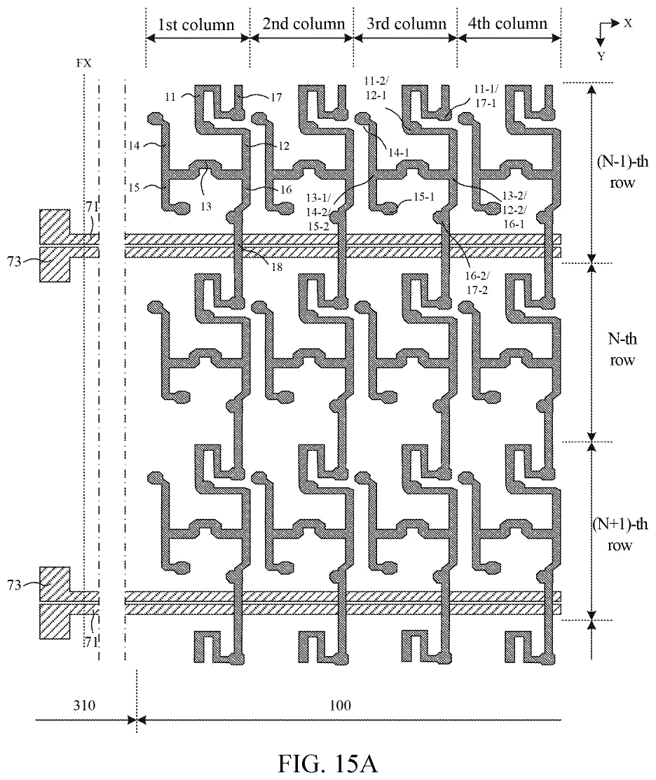

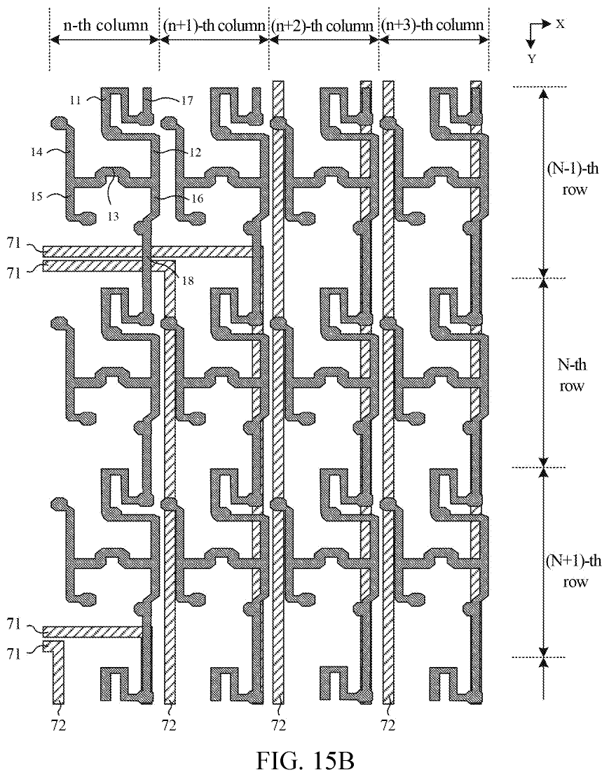

(2) A pattern of a semiconductor layer is formed. In an exemplary embodiment, forming the pattern of the semiconductor layer may include: depositing sequentially a first insulating thin film and a semiconductor thin film on the base substrate, and patterning the semiconductor thin film through a patterning process to form a first insulating layer covering the base substrate and the pattern of the semiconductor layer provided on the first insulating layer, as shown in FIGS. 15A and 15B, wherein FIG. 15A is a schematic diagram of a planar structure of an area B in FIG. 6, and FIG. 15B is a schematic diagram of a planar structure of an area C in FIG. 6.

In an exemplary embodiment, the pattern of the semiconductor layer of each circuit unit in the display area may at least include a first active layer 11 of the first transistor T1 to a seventh active layer 17 of the seventh transistor T7, and a connection line 18. The first active layer 11 to the seventh active layer 17 are an integral structure interconnected to each other, and in the second direction Y, the sixth active layer 16 of the circuit unit in the N-th unit row and the seventh active layer 17 of the circuit unit in the (N+1)-th unit row are connected to each other through the connection line 18.

In an exemplary embodiment, in the first direction X, the second active layer 12 and the sixth active layer 16 may be located on a same side of the third active layer 13 in the present circuit unit, the fourth active layer 14 and the fifth active layer 15 may be located on a same side of the third active layer 13 in the present circuit unit, and the second active layer 12 and the fourth active layer 14 may be located on different sides of the third active layer 13 of the present circuit unit. In the second direction Y, the first active layer 11, the second active layer 12, and the fourth active layer 14, and the seventh active layer 17 may be located on a side of the third active layer 13 in the present circuit unit in a direction opposite to the second direction Y, and the fifth active layer 15 and the sixth active layer 16 may be located on a side of the third active layer 13 in the present circuit unit in the second direction Y.

In an exemplary embodiment, a shape of the first active layer 11 may be an “n” shape, shapes of the second active layer 12 and the fifth active layer 15 may be an “L” shape, a shape of the third active layer 13 may be an “Ω” shape, shapes of the fourth active layer 14, the sixth active layer 16, and the seventh active layer 17 may be an “I” shape.

In an exemplary embodiment, an active layer of each transistor may include a first region, a second region, and a channel region located between the first region and the second region. In an exemplary embodiment, a first region 11-1 of the first active layer may serve as a first region 17-1 of the seventh active layer, a second region 11-2 of the first active layer may serve as a first region 12-1 of the second active layer, a first region 13-1 of the third active layer may simultaneously serve as a second region 14-2 of the fourth active layer and a second region 15-2 of the fifth active layer, a second region 13-2 of the third active layer may simultaneously serve as the second region 12-2 of the second active layer and a first region 16-1 of the sixth active layer, a second region 16-2 of the sixth active layer in the present circuit unit may serve as a second region 17-2 of the seventh active layer in a circuit unit of a next row, and a first region 14-1 of the fourth active layer and a first region 15-1 of the fifth active layer may be provided separately.

In an exemplary embodiment, an orthographic projection of the first sub-line 71 on the base substrate does not overlap with orthographic projections of the first active layer 11 to the seventh active layer 17 on the base substrate, and the orthographic projection of the first sub-line 71 on the base substrate at least partially overlaps with an orthographic projection of the connection line 18 on the base substrate.

In an exemplary embodiment, an orthographic projection of the second sub-line 72 on the base substrate at least partially overlaps with an orthographic projection of the third active layer13 on the base substrate, and the orthographic projection of the second sub-line 72 on the base substrate at least partially overlaps with the orthographic projection of the connection line 18 on the base substrate.

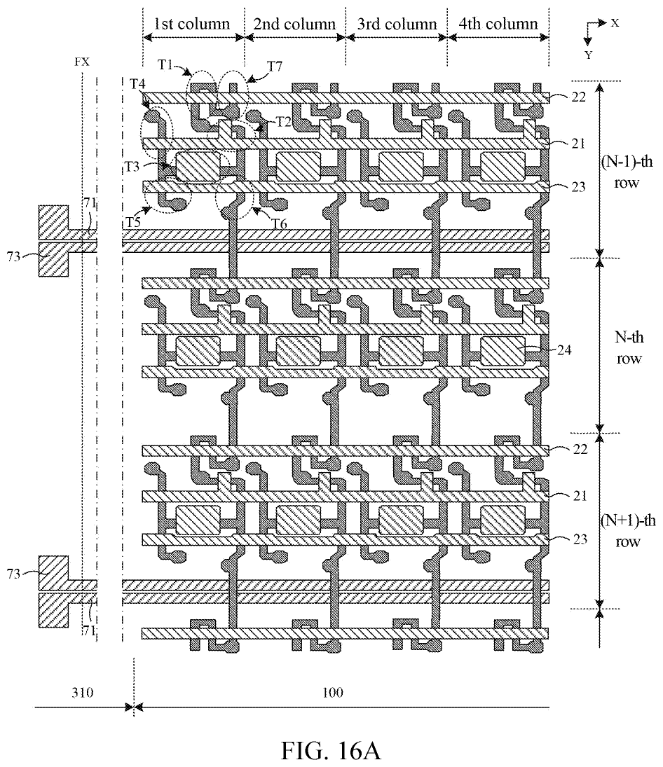

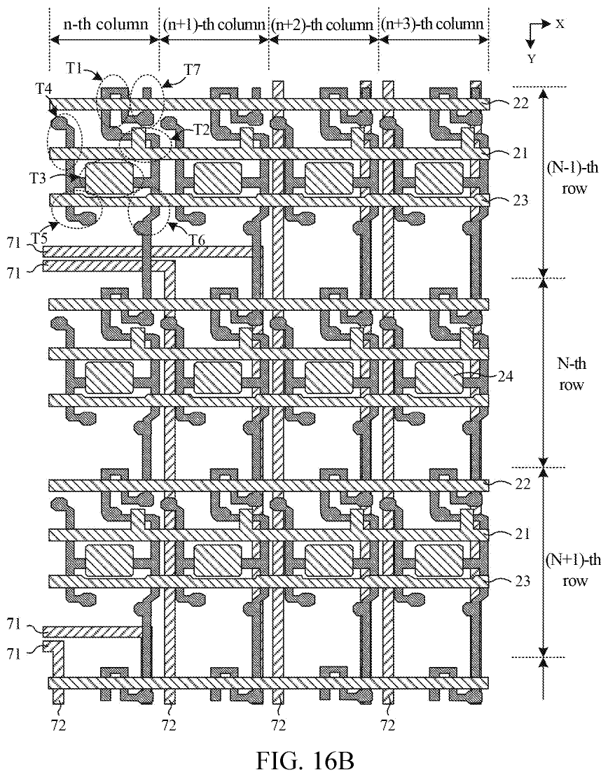

(3) A pattern of a first conductive layer is formed. In an exemplary embodiment, forming the pattern of the first conductive layer may include: sequentially depositing a second insulating thin film and a first conductive thin film on the base substrate on which the above-mentioned patterns have been formed, and patterning the first conductive thin film by a patterning process to form a second insulating layer that covers a pattern of the semiconductor layer and form the pattern of the first conductive layer provided on the second insulating layer, as shown in FIGS. 16A and 16B, wherein FIG. 16A is a schematic diagram of a planar structure of an area B in FIG. 6, and FIG. 16B is a schematic diagram of a planar structure of an area C in FIG. 6. In an exemplary embodiment, the first conductive layer may be referred to as a first gate metal (GATE1) layer.

In an exemplary embodiment, the pattern of the first conductive layer of each circuit unit in the display area may at least include, a first scan signal line 21, a second scan signal line 22, a light emitting control line 23, a first plate 24 of a storage capacitor.

In an exemplary embodiment, the first electrode plate 24 may be in a shape of a rectangle, and a chamfer may be provided at a corner of the rectangle. An orthographic projection of the first electrode plate 24 on the base substrate is at least partially overlapped with an orthographic projection of the third active layer of the third transistor T3 on the base substrate. In an exemplary embodiment, the first electrode plate 24 may serve as an electrode plate of the storage capacitor and a gate electrode of the third transistor T3 simultaneously.

In an exemplary embodiment, the shape of the first scan signal line 21 may be a line shape in which the main body part the first scan signal line 21 extends in the first direction X, and the first scan signal line 21 may be located on a side of the first electrode plate 24 of the present circuit unit in a direction opposite to the second direction Y. The first scan signal line 21 of each circuit unit is provided with a gate block, a first end of the gate block is connected to the first scan signal line 21, and a second end of the gate block extends towards a direction away from the first electrode plate 24. An area where the first scan signal line 21 and the gate block overlap with the second active layer of the present circuit unit serves as a gate electrode of the second transistor T2 with a double-gate structure, and an area where the first scan signal line 21 overlaps with the fourth active layer of the present circuit unit serves as a gate electrode of the fourth transistor T4.

In an exemplary embodiment, the second scan signal line 22 may be of a line shape in which a main body part of the second scan signal line 22 extends in the first direction X, the second scan signal line 22 may be located on a side of the first scan signal line 21 of the present circuit unit away from the first electrode plate 24, an area where the second scan signal line 22 overlaps with the first active layer of the present circuit unit serves as a gate electrode of the first transistor T1 with a double-gate structure, and an area where the second scan signal line 22 overlaps with the seventh active layer of the present circuit unit serves as a gate electrode of the seventh transistor T7.

In an exemplary embodiment, the light emitting control line 23 may be of a line shape in which a main body part of the light emitting control line 23 extends in the first direction X, the light emitting control line 23 may be located on a side of the first electrode plate 24 of the present circuit unit in the second direction Y, an area where the light emitting control line 23 overlaps with the fifth active layer of the present circuit unit serves as a gate electrode of the fifth transistor T5, and an area where the light emitting control line 23 overlaps with the sixth active layer of the present circuit unit serves as a gate electrode of the sixth transistor T6.

In an exemplary embodiment, the first scan signal line 21, the second scan signal line 22, and the light emitting control line 23 may be in an equal width design, or may be in a non-equal width design, may be straight lines, or may be polygonal lines, which can not only facilitate the layout of the pixel structure, but also reduce the parasitic capacitances between the signal lines, which is not limited in the present disclosure.

In an exemplary embodiment, an orthographic projection of the first sub-line 71 on the base substrate does not overlap with orthographic projections of the first scan signal line 21, the second scan signal line 22, the light emitting control line 23 and the first electrode plate 24 of the storage capacitor on the base substrate, and an orthographic projection of the second sub-line 72 on the base substrate does not overlap with an orthographic projection of the first electrode plate 24 of the storage capacitor on the base substrate.

In an exemplary embodiment, after the pattern of the first conductive layer is formed, the semiconductor layer may be subjected to a conductive treatment by using the first conductive layer as a shield. The semiconductor layer in a region which is shielded by the first conductive layer, forms channel regions of the first transistor T1 to the seventh transistor T7, and the semiconductor layer in a region, which is not shielded by the first conductive layer, is subjected to a conductive treatment, that is, first regions and second regions of the first transistor T1 to the seventh active layer are all subjected to the conductive treatment.

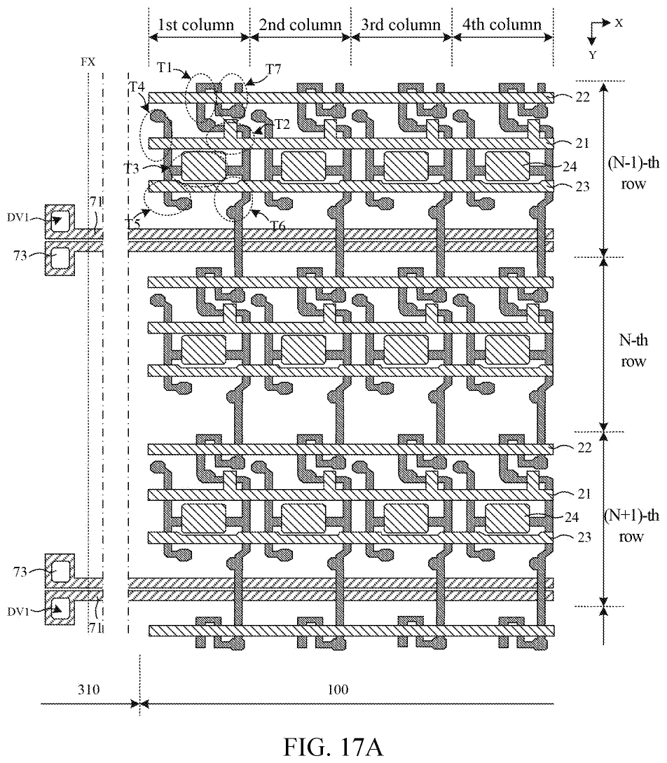

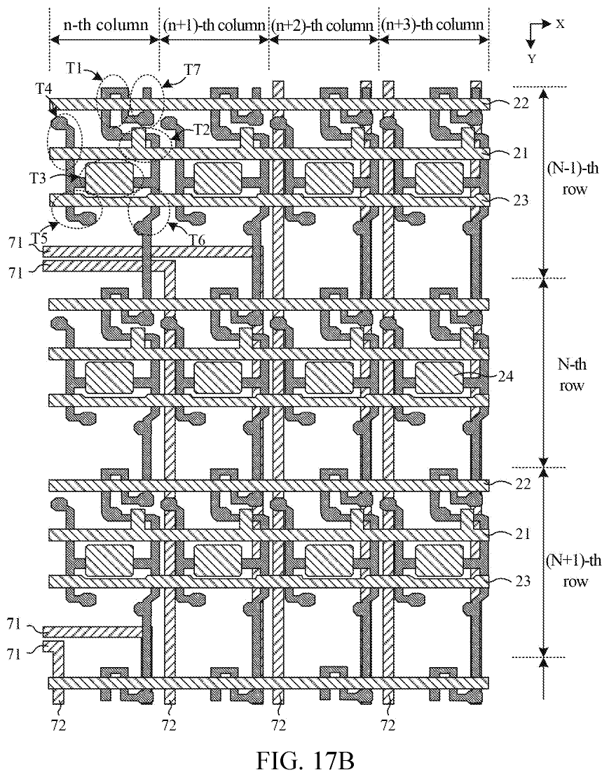

(4) A pattern of a first lap via is formed. In an exemplary embodiment, forming the pattern of the first lap via may include: depositing a third insulating thin film on the base substrate on which the above-mentioned patterns have been formed, patterning the third insulating thin film by a patterning process to form a third insulating layer covering the first conductive layer, and form a plurality of first lap vias DV1 on the third insulating layer, as shown in FIGS. 17A and 17B, wherein FIG. 17A is a schematic diagram of a planar structure of an area B in FIG. 6, and FIG. 17B is a schematic diagram of a planar structure of an area C in FIG. 6.

In an exemplary embodiment, a plurality of first lap vias DV1 may be provided on a side of the encapsulation line FX away from the display area 100, i.e., the first lap vias DV1 may be provided in the non-encapsulation region in the side bezel region 310.

In an exemplary embodiment, an orthographic projection of the first lap via DV1 on the base substrate may be located within a range of an orthographic projection of the first connection block 73 on the base substrate, the third insulating layer, the second insulating layer, the first insulating layer, the second barrier layer and the second flexible layer in the first lap via DV1 are removed to expose a surface of the first connection block 73, and the first lap via DV1 is configured to connect the second connection line formed subsequently with the first connection block 73.

In an exemplary embodiment, a plurality of first lap vias DV1 may be located on a straight line extending in the second direction Y, and a shape of the first lap via DV1 may be any one or more of the following: a triangle, a rectangle, a pentagon, a hexagon, a circle, and an ellipse.

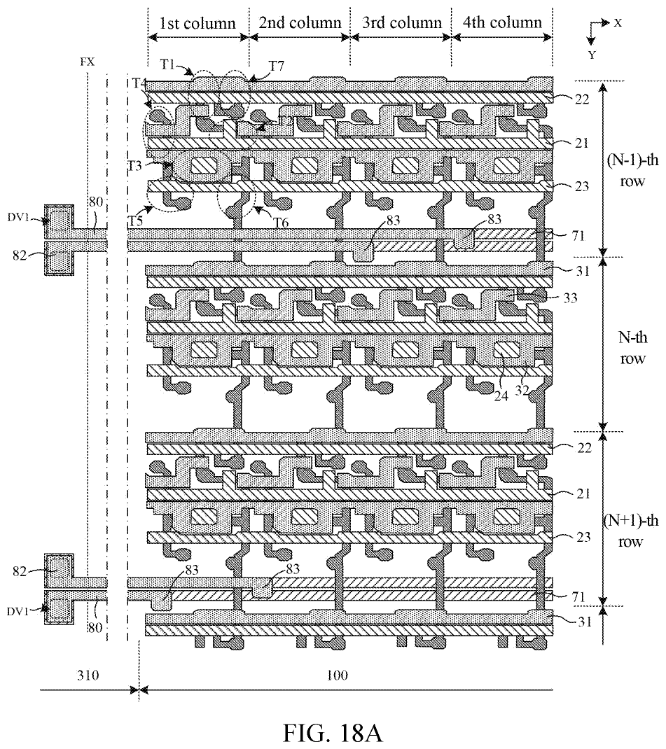

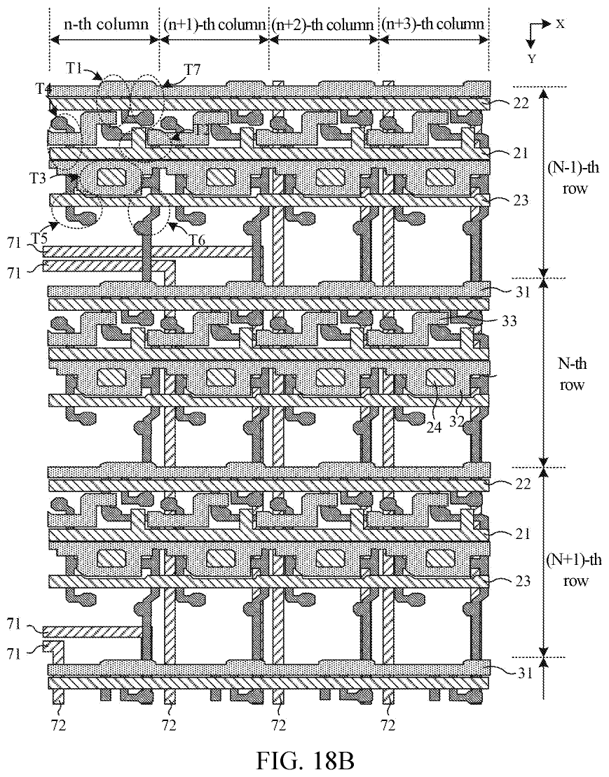

(5) A pattern of a second conductive layer is formed. In an exemplary embodiment, forming the pattern of the second conductive layer may include: depositing a second conductive thin film on the base substrate on which the above-mentioned patterns have been formed, and patterning the second conductive thin film by a patterning process to form the pattern of the second conductive layer on the third insulating layer, as shown in as shown in FIGS. 18A and 18B, wherein FIG. 18A is a schematic diagram of a planar structure of an area B in FIG. 6, and FIG. 18B is a schematic diagram of a planar structure of an area C in FIG. 6. In an exemplary embodiment, the second conductive layer may be referred to as a second gate metal (GATE2) layer.

In an exemplary embodiment, the pattern of the second conductive layer of each circuit unit in the display area at least includes an initial signal line 31, a second electrode plate 32 of a storage capacitor, and a shield electrode 33.

In an exemplary embodiment, the initial signal line 31 may be of a line shape in which a main body part of the initial signal line 31 extends in the first direction X. The initial signal line 31 may be located on a side of the second scan signal line 22 of the present circuit unit away from the first scan signal line 21, and the initial signal line 31 is configured to connect with a first electrode of the first transistor T1 formed subsequently (also a first electrode of the seventh transistor T7).

In an exemplary embodiment, a profile of the second electrode plate 32 may be in a shape of a rectangle, a corner of the rectangle may be provided with a chamfer, an orthographic projection of the second electrode plate 32 on the base substrate is at least partially overlapped with an orthographic projection of the first electrode plate 24 on the base substrate, the second electrode plate 32 may serve as the other electrode plate of the storage capacitor, and the first electrode plate 24 and the second electrode plate 32 constitute the storage capacitor of the pixel drive circuit.

In an exemplary embodiment, the second electrode plate 32 is provided with an opening which may have a rectangular shape and may be located in a middle of the second electrode plate 32, so that the second electrode plate 32 forms an annular structure. The opening exposes the third insulating layer covering the first electrode plate 24, and an orthographic projection of the first electrode plate 24 on the base substrate includes an orthographic projection of the opening on the base substrate. In an exemplary embodiment, the opening is configured to accommodate a first via formed subsequently, and the first via is located in the opening and exposes the first electrode plate 24, so that a second electrode of the first transistor T1 formed subsequently is connected to the first electrode plate 24.

In an exemplary embodiment, second electrode plates 32 of two adjacent sub-pixels in one unit row are connected to each other by an electrode plate connection line. In an exemplary embodiment, since the second electrode plate 32 in each circuit unit is connected to a first power supply line formed subsequently, the second electrode plates 32 in adjacent circuit units are formed into an integral structure interconnected to each other through the electrode plate connection line. The second electrode plate of the integral structure may be reused as a power supply signal line to ensure a plurality of second electrode plates in one unit row have the equal potential, which is beneficial to improving uniformity of a panel and avoiding a poor display of the display substrate, thereby ensuring a display effect of the display substrate.

In an exemplary embodiment, a shape of the shield electrode 33 may be a straight line extending in the first direction X, the shield electrode 33 may be provided between the first scan signal line 21 and the second scan signal line 22, an orthographic projection of a first end of the shield electrode 33 on the base substrate at least partially overlaps with an orthographic projection of a portion of the second active layer located between two gate electrodes on the base substrate, an orthographic projection of a second end of the shield electrode 33 on the base substrate at least partially overlaps with an orthographic projection of a second region of the first active layer on the base substrate, and the shield electrode 33 is connected to a first power supply line formed subsequently, and is configured to shield a key node of a pixel drive circuit.

In an exemplary embodiment, the pattern of the second conductive layer may further include a plurality of second connection lines 80. A shape of the second connection line 80 may be a line shape in which a main body part of the second connection line 80 extends in the second direction Y, a first end of the second connection line 80 (an end away from the display area 100) is provided with a second connection block 82, and a second end of the second connection line 80 (an end located at the display area 100) is provided with a third connection block 83.

In an exemplary embodiment, the second connection block 82 and the third connection block 83 may have a rectangular shape. The second connection block 82 is connected to the first connection block 73 through the first lap via DV1, and the third connection block 83 is configured to be connected to a data signal line formed subsequently.

In an exemplary embodiment, a plurality of second connection blocks 82 of a plurality of second connection lines 80 may be located on a straight line extending in the second direction Y, and a plurality of third connection blocks 83 of a plurality of second connection lines 80 may be located in different unit columns to be respectively connected to data signal lines of different unit columns.

In an exemplary embodiment, an area of the second connection block 82 may be smaller than an area of the first connection block 73, and an orthographic projection of the second connection block 82 on the base substrate may be located within a range of an orthographic projection of the first connection block 73 on the base substrate.

In an exemplary embodiment, the second connection block 82 covers the first connection block 73 exposed inside the bottom of the first lap via DV1 and covers the flexible layer and a plurality of inorganic layers exposed inside an inner side wall of the first lap via DV1, and the second connection block 82 covers the third insulating layer outside the first lap via DV1.

In an exemplary embodiment, for a first sub-line 71 and a second connection line 80 connected to each other through the first lap via DV1, an orthographic projection of the second connection line 80 on the base substrate at least partially overlaps with an orthographic projection of the first sub-line 71 on the base substrate, forming upper and lower stacked traces of the first sub-line 71 and the second connection line 80 to reduce the parasitic capacitance for transmitting the data signals.

In an exemplary embodiment, an orthographic projection of the second connection line 80 on the base substrate may be located within a range of an orthographic projection of the first sub-line 71 on the base substrate.

In an exemplary embodiment, a distance between the two second connection lines 80 in the sub-line group located between the (N−1)-th row and the N-th row may be equal to a distance between the two second connection lines 80 in the sub-line group located between the (N+1)-th row and the (N+2)-th row.

In an exemplary embodiment, an orthographic projection of the first sub-line 71 on the base substrate does not overlap with orthographic projections of the initial signal line 31, the second electrode plate 32 of the storage capacitor and the shield electrode 33 on the base substrate, an orthographic projection of the second connection line 80 on the base substrate does not overlap with the orthographic projections of the initial signal line 31, the second electrode plate 32 of the storage capacitor and the shield electrode 33 on the base substrate, and an orthographic projection of the second sub-line 72 on the base substrate does not overlap with an orthographic projection of the second electrode plate 32 of the storage capacitor on the base substrate.

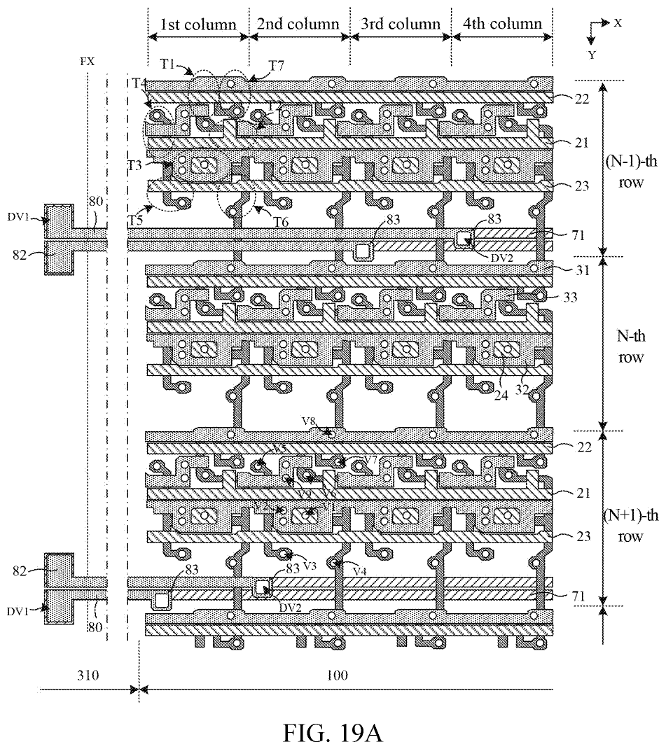

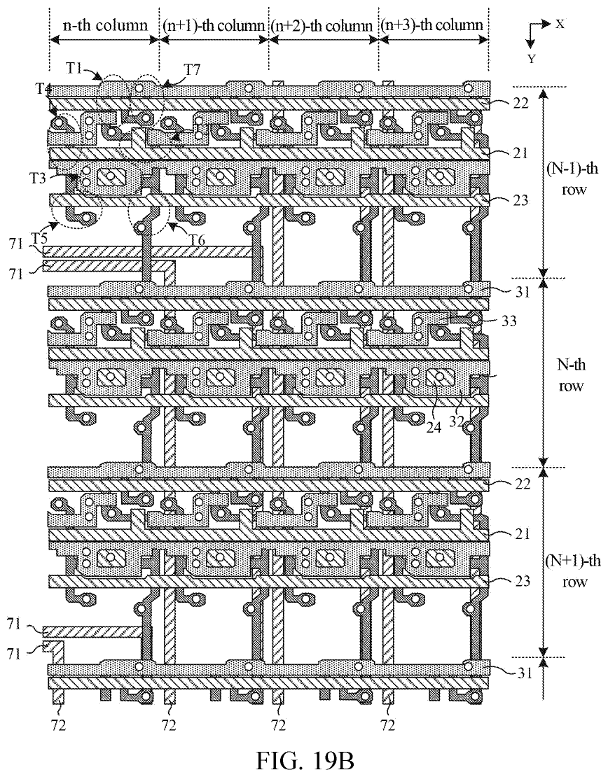

(6) A pattern of a fourth insulating layer is formed. In an exemplary embodiment, forming the pattern of the fourth insulating layer may include: depositing a fourth insulating thin film on the base substrate on which the afore-mentioned patterns have been formed, and patterning the fourth insulating thin film by a patterning process, to form the fourth insulating layer covering the second conductive layer, wherein the fourth insulating layer is provided with a plurality of vias thereon, as shown in FIGS. 19A and 19B, wherein FIG. 19A is a schematic diagram of a planar structure of an area B in FIG. 6, and FIG. 19B is a schematic diagram of a planar structure of an area C in FIG. 6.

In an exemplary embodiment, the plurality of vias of each circuit unit in the display area at least include a first via V1, a second via V2, a third via V3, a fourth via V4, a fifth via V5, a sixth via V6, a seventh via V7, an eighth via V8 and a ninth via V9.

In an exemplary embodiment, an orthographic projection of the first via V1 on the base substrate is within a range of an orthographic projection of the opening on the base substrate, the fourth insulating layer and the third insulating layer in the first via V1 are etched away to expose a surface of the first electrode plate 24, and the first via V1 is configured such that the second electrode of the first transistor T1 formed subsequently (also the first electrode of the second transistor T2) is connected to the first electrode plate 24 through this first via V1.

In an exemplary embodiment, an orthographic projection of the second via V2 on the base substrate is within a range of an orthographic projection of the second electrode plate 32 on the base substrate, the fourth insulating layer in the second via V2 is etched away to expose a surface of the second electrode plate 32, and the second via V2 is configured such that the first power supply line formed subsequently is connected to the second electrode plate 32 through the second via V2. In an exemplary embodiment, there may be a plurality of second vias V2, and the plurality of second vias V2 may be provided in sequence in the second direction Y to improve connection reliability.

In an exemplary embodiment, an orthographic projection of the third via V3 on the base substrate is within a range of an orthographic projection of the first region of the fifth active layer on the base substrate. The fourth insulating layer, the third insulating layer and the second insulating layer in the third via V3 are etched away to expose a surface of the first region of the fifth active layer, and the third via V3 is configured such that the first power supply line formed subsequently is connected to the first region of the fifth active layer through the third via V3.

In an exemplary embodiment, an orthographic projection of the fourth via V4 on the base substrate is within a range of an orthographic projection of the second region of the sixth active layer (also the second region of the seventh active layer) on the base substrate. The fourth insulating layer, the third insulating layer and the second insulating layer in the fourth via V4 are etched away to expose a surface of the second region of the sixth active layer, and the fourth via V4 is configured such that the second electrode of the sixth transistor T6 formed subsequently (also the second electrode of the seventh transistor T7) is connected to the second region of the sixth active layer through the fourth via V4.

In an exemplary embodiment, an orthographic projection of the fifth via V5 on the base substrate is within a range of an orthographic projection of the first region of the fourth active layer on the base substrate. The fourth insulating layer, the third insulating layer and the second insulating layer in the fifth via V5 are etched away to expose a surface of the first region of the fourth active layer, and the fifth via V5 is configured such that the data signal line formed subsequently is connected to the first region of the fourth active layer through the fifth via V5.

In an exemplary embodiment, an orthographic projection of the sixth via V6 on the base substrate is within a range of an orthographic projection of the second region of the first active layer (also the first region of the second active layer) on the base substrate. The fourth insulating layer, the third insulating layer and the second insulating layer in the sixth via V6 are etched away to expose a surface of the second region of the first active layer, the sixth via V6 is configured such that the second electrode of the first transistor T1 formed subsequently (also the first electrode of the second transistor T2) is connected to the second region of the first active layer (also the first region of the second active layer) through the sixth via V6.

In an exemplary embodiment, an orthographic projection of the seventh via V7 on the base substrate is within a range of an orthographic projection of the first region of the first active layer (also the first region of the seventh active layer) on the base substrate. The fourth insulating layer, the third insulating layer and the second insulating layer in the seventh via V7 are etched away to expose a surface of the first region of the first active layer, the seventh via V7 is configured such that the first electrode of the first transistor T1 formed subsequently (also the first electrode of the seventh transistor T7) is connected to the first region of the first active layer (also the first region of the seventh active layer) through the seventh via V7.

In an exemplary embodiment, an orthographic projection of the eighth via V8 on the base substrate is within a range of an orthographic projection of the initial signal line 31 on the base substrate. The fourth insulating layer in the eighth via V8 are etched away to expose a surface of the initial signal line 31, and the eighth via V8 is configured such that the first electrode of the first transistor T1 formed subsequently (also the first electrode of the seventh transistor T7) is connected to the initial signal line 31 through the via V8.

In an exemplary embodiment, an orthographic projection of the ninth via V9 on the base substrate is within a range of an orthographic projection of the shield electrode 33 on the base substrate. The fourth insulating layer in the ninth via V9 is etched away, exposing the surface of the shield electrode 33, and the ninth via V9 is configured such that the first power supply line subsequently formed is connected to the shield electrode 33 through the ninth via V9. In an exemplary embodiment, there may be a plurality of ninth vias V9, and the plurality of ninth vias V9 may be provided in sequence in the second direction Y to improve the connection reliability.

In an exemplary embodiment, the fourth insulating layer may further be provided with a plurality of second lap vias DV2 which may be provided in some of the circuit units. An orthographic projection of the second lap via DV2 on the base substrate is within a range of an orthographic projection of the third connection block 83 of the second connection line 80 on the base substrate, the fourth insulating layer in the second lap via DV2 is etched away to expose a surface of the third connection block 83, and the second lap via DV2 is configured to connect the data signal line formed subsequently to the second connection line 80 through itself.

In an exemplary embodiment, a distance between the two second lap vias DV2 in the sub-line group located between the (N−1)-th row and the N-th row may be equal to a distance between the two second lap vias DV2 in the sub-line group located between the (N+1)-th row and the (N+2)-th row.

In an exemplary embodiment, since the plurality of first lap vias DV1 are provided in the side bezel region and the plurality of second lap vias DV2 are provided in the display area, orthographic projections of the second lap vias DV2 on the base substrate do not overlap with orthographic projections of the first lap vias on the base substrate.

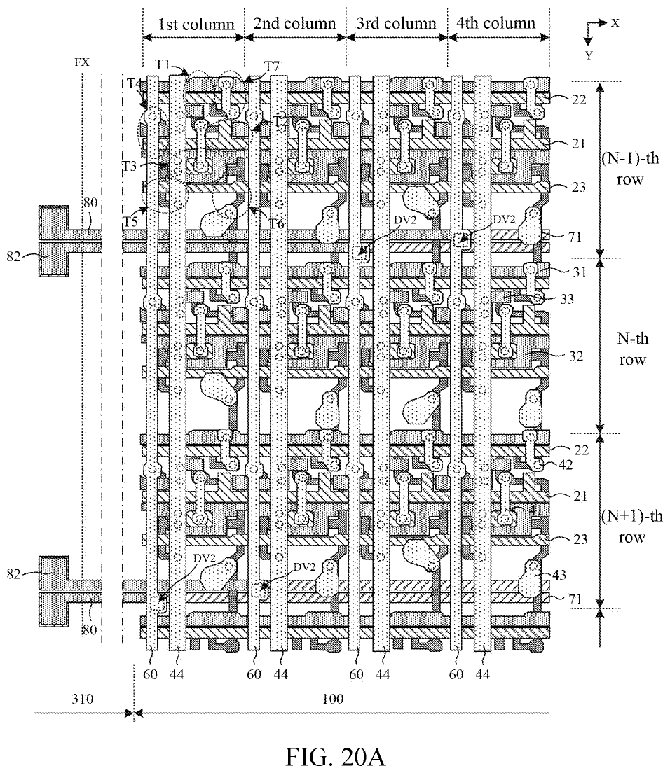

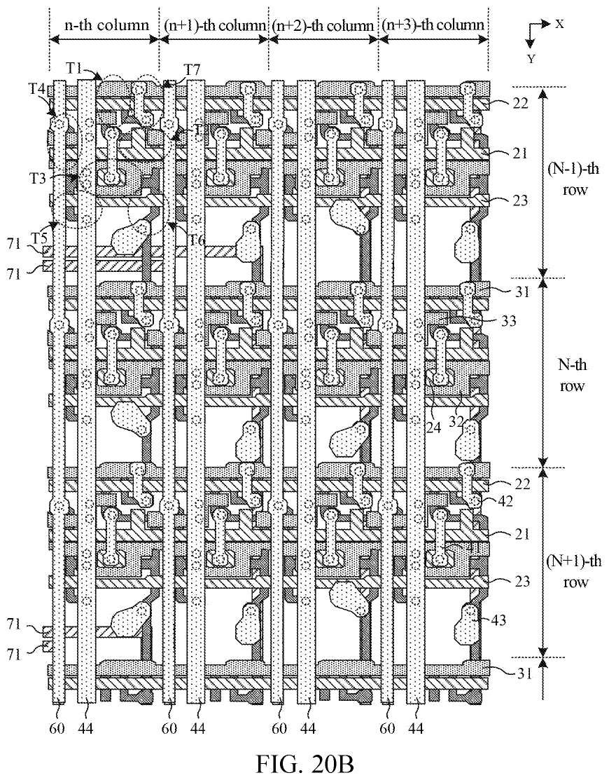

(7) A pattern of a third conductive layer is formed. In an exemplary embodiment, forming the third conductive layer may include: depositing a third conductive thin film on the base substrate on which the afore-mentioned patterns have been formed, and patterning the third conductive thin film by a patterning process, to form the third conductive layer provided on the fourth insulating layer, as shown in FIGS. 20A and 20B, wherein FIG. 20A is a schematic diagram of a planar structure of an area B in FIG. 6, and FIG. 20B is a schematic diagram of a planar structure of an area C in FIG. 6. In an exemplary embodiment, the third conductive layer may be referred to as a first source and drain metal (SD1) layer.

In an exemplary embodiment, the third conductive layer of each circuit unit in the display area at least includes a first connection electrode 41, a second connection electrode 42, a third connection electrode 43, a first power supply line 44, and a data signal line 60.

In an exemplary embodiment, the first connection electrode 41 may be in a strip shape in which a main body part of the first connection electrode 41 extends in the second direction Y. The first end of the first connection electrode 41 is connected to the first electrode plate 24 through the first via V1, and the second end of the first connection electrode 41 is connected to the second area of the first active layer (also is the first area of the second active layer) through the sixth via V6, so that the first electrode plate 24, the second area of the first active layer and the first area of the second active layer have same potential. In an exemplary embodiment, the first connection electrode 41 may serve as the second electrode of the first transistor T1 and the first electrode of the second transistor T2 simultaneously.

In an exemplary embodiment, the second connection electrode 42 may be in a strip shape in which a main body part the second connection electrode 42 extends in the second direction Y. A first end of the second connection electrode 42 is connected to the initial signal line 31 through the eighth via V8, and a second end of the second connection electrode 42 is connected to the first area of the first active layer (also is a first area of the seventh active layer) through the seventh via V7. In an exemplary embodiment, the second connection electrode 42 may serve as the first electrode of the first transistor T1 and the first electrode of the seventh transistor T7 simultaneously.

In an exemplary embodiment, the third connection electrode 43 may be in a block shape, and the third connection electrode 43 is connected to the second region of the sixth active layer (also the second region of the seventh active layer) through the fourth via V4. In an exemplary embodiment, the third connection electrode 43 may serve as the second electrode of the sixth transistor T6 and the second electrode of the seventh transistor T7 simultaneously, and the third connection electrode 43 may serve as an anode connection electrode, and is configured to be connected to an anode formed subsequently. In an exemplary embodiment, shapes of the third connection electrodes 43 of various circuit units may be different to connect the corresponding anodes.

In an exemplary embodiment, the first power supply line 44 may be in a straight line shape in which a main body part of the first power supply line 44 extends in the second direction Y. On the one hand, the first power supply line 44 is connected to the second electrode plate 32 through the second via V2, on the other hand, the first power supply line 44 is connected to the first region of the fifth active layer through the third via V3, and on still another hand, the first power supply line 44 is connected to the shield electrode 33 through the ninth via V9, so that a power supply signal is written to the first electrode of the fifth transistor T5, and the second electrode plate 32, the first electrode of the fifth transistor T5, and the shield electrode 33 have the same potential.

In an exemplary embodiment, the data signal line 60 may be in a straight line shape in which a main body part of the data signal line 60 extends in the second direction Y. The data signal line 60 is connected to a first region of the fourth active layer through the fifth via V5, thus achieving that a data signal is written into a first electrode of the fourth transistor T4.

In an exemplary embodiment, the data signal line 60 of each unit column is further connected to the second connection line 80 through the second lap via DV2. Since the second connection line 80 is connected to the first connection line 70 through the first lap via, thus achieving that the data signal line 60 of the display area 100 is connected to a lead line of the bonding area through the first connection line 70 and the second connection line 80.

In an exemplary embodiment, an orthographic projection of the first sub-line 71 on the base substrate does not overlap with orthographic projections of the first connection electrode 41, the second connection electrode 42 and the third connection electrode 43 on the base substrate, and an orthographic projection of the second connection line 80 on the base substrate does not overlap with the orthographic projections of the first connection electrode 41, the second connection electrode 42 and the third connection electrode 43 on the base substrate.

In an exemplary embodiment, an orthographic projection of the at least one second sub-line 72 on the base substrate at least partially overlaps with an orthographic projection of the data signal line 60 on the base substrate, and the orthographic projection of the at least one second sub-line 72 on the base substrate does not overlap with orthographic projections of the first connection electrode 41 and the second connection electrode 42 on the base substrate.

The subsequent preparation process may include forming a first planarization layer and the like, and the drive circuit layer is prepared on the glass carrier plate.

In an exemplary embodiment, on a plane parallel to the display substrate, the drive circuit layer of the display area may include a plurality of circuit units, each of the circuit units may include a pixel drive circuit, and the pixel drive circuit is connected to a first scan signal line 21, a second scan signal line 22, a light emitting control line 23, an initial signal line 31, a first power supply line 44, and a data signal line 60, respectively. The drive circuit layers of the display area and the side bezel region may further include a plurality of first connection lines 70 and a plurality of second connection lines 80. The data signal line 60 is connected to the second connection line 80 through the second lap via DV2, and the second connection line 80 is connected to the first connection line 70 through the first lap via DV1.

In an exemplary embodiment, on a plane perpendicular to the display substrate, the drive circuit layer may be provided on the base substrate. The base substrate may include a first flexible layer 10A, a first barrier layer 10B, a base substrate conductive layer, a second flexible layer 10C, and a second barrier layer 10D that are stacked, and the base substrate conductive layer may at least include first connection lines 70 located in the display area and the side bezel region (the first sub-lines and the second sub-lines connected to each other). The drive circuit layer may at least include a first insulating layer, a semiconductor layer, a second insulating layer, a first conductive layer, a third insulating layer, a second conductive layer, a fourth insulating layer and a third conductive layer stacked in sequence on the base substrate. The semiconductor layer may at least include active layers of the first transistor to the seventh transistor, the first conductive layer may at least include a first scan signal line 21, a second scan signal line 22, a light emitting control line 23, and a first electrode plate 24 of a storage capacitor, and the second conductive layer may at least include an initial signal line 31, a second electrode plate 32 of the storage capacitor, a shield electrode 33, and a second connection line 80, wherein the second connection line 80 is connected to the first connection line 70 through the first lap via DV1. The third conductive layer may at least include a first connection electrode 41, a second connection electrode 42, a third connection electrode 43, a first power supply line 44, and the data signal line 60, and the data signal line 60 are connected to the second connection line 80 through a second lap via DV2.

In an exemplary embodiment, the first conductive layer, the second conductive layer, and the third conductive layer may be made of a metal material, for example, any one or more of Argentum (Ag), Copper (Cu), Aluminum (Al), and Molybdenum (Mo), or an alloy material of the above-mentioned metals, for example, an Aluminum-Neodymium alloy (AlNd) or a Molybdenum-Niobium alloy (MoNb), and may be in a single-layer structure, or in a multilayer composite structure such as Mo/Cu/Mo, etc. The first insulating layer, the second insulating layer, the third insulating layer, and the fourth insulating layer may be made of any one or more of Silicon Oxide (SiOx), Silicon Nitride (SiNx), and Silicon Oxynitride (SiON), and may be a single layer, a multi-layer, or a composite layer. The first insulating layer may be referred to as a buffer layer, the second insulating layer and the third insulating layer may be referred to as Gate Insulator (GI) layers, and the fourth insulating layer may be referred to as an Interlayer Dielectric (ILD) layer. The semiconductor layer may be made of materials such as amorphous indium gallium zinc oxide (a-IGZO), zinc oxynitride (ZnON), indium zinc tin oxide (IZTO), amorphous silicon (a-Si), polysilicon (p-Si), hexathiophene, or polythiophene. That is, the embodiment of the present invention is applicable to thin film transistors that are prepared based on oxide technology, silicon technology or organic technology.

In an exemplary embodiment, after the drive circuit layer is prepared, a light emitting structure layer and an encapsulation structure layer are prepared sequentially on the drive circuit layer. Preparing the light emitting structure layer may include: an anode conductive layer is formed at first, wherein the anode conductive layer may at least include a plurality of anode patterns; then a pixel definition layer is formed, and the pixel definition layer of each circuit unit is provided with a pixel opening in which the pixel definition layer is removed to expose an anode of the circuit unit where the pixel definition layer is located; subsequently, an organic light emitting layer is formed using an evaporation or ink-jet printing process, and a cathode is formed on the organic light emitting layer. The encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is provided between the first encapsulation layer and the third encapsulation layer, which can ensure that external water and oxygen cannot enter the light emitting structure layer.

In an exemplary embodiment, the encapsulation structure layer may be formed in the display area and the bezel region, and the encapsulation structure layer in the bezel region may be located on a side of the encapsulation line FX close to the display area.

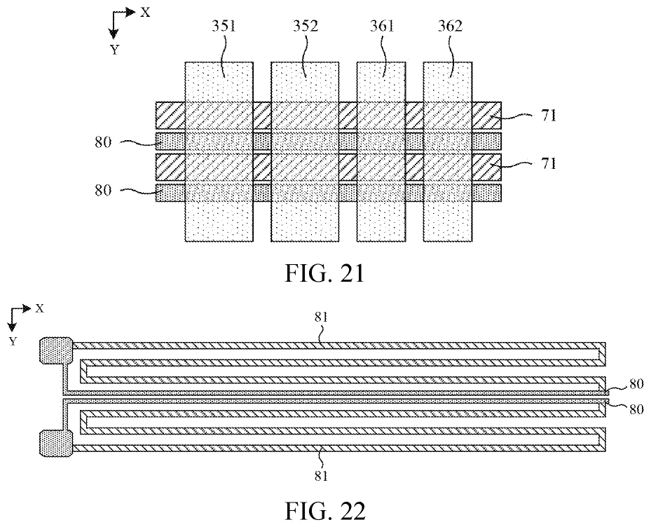

FIG. 21 is a schematic diagram of a structure of a first overlapping area according to an exemplary embodiment of the present disclosure. As shown in FIG. 21, the bezel area of the display substrate may at least include a light emitting start signal (ESTV) line 351, a scan start signal (GSTV) line 352, a first clock signal (ECK) line 361, and a second clock signal (ECB) line 362, which may have a line shape extending in the second direction Y and may be provided in the gate circuit region. Since the first sub-line 71 and the second connection line 80 in the lead group have a line shape extending laterally, and the light emitting start signal line 351, the scan start signal line 352, the first clock signal line 361 and the second clock signal line 362 have a line shape extending vertically, the first sub-line 71 and the second connection line 80 pass below the light emitting start signal line 351, the scan start signal line 352, the first clock signal line 361 and the second clock signal line 362. Orthographic projections of the first sub-line 71 and the second connection line 80 on the base substrate have a first overlapping area with orthographic projections of the light emitting start signal line 351, the scan start signal line 352, the first clock signal line 361 and the second clock signal line 362 on the base substrate.

In an exemplary embodiment, an orthographic projection of the first sub-line 71 on the base substrate does not overlap with an orthographic projection of the second connection line 80 on the base substrate. By arranging that the first sub-line and the second connection line in the first overlapping area do not overlap, the present disclosure can ensure that the light emitting start signal line 351, the scan start signal line 352, the first clock signal line 361 and the second clock signal line 362 will not have large climbing due to the first sub-line and the second connection line provided below, thus avoiding a short circuit caused by metal residue at the climbing place, and improving the process quality.

In an exemplary embodiment, in the first overlapping area, various means may be adopted to prevent the first sub-line 71 and the second connection line 80 located in the first overlapping area from overlapping. For example, the first sub-line 71 and/or the second connection line 80 may avoid each other by a wiring bending manner. For another example, the first sub-line 71 and/or the second connection line 80 may avoid each other by narrowing the line width. The present disclosure is not limited thereto.

In an exemplary embodiment, in the side bezel region other than the first overlapping area, for a first sub-line 71 and a second connection line 80 transmitting the same data signal, an orthographic projection of the first sub-line 71 on the base substrate at least partially overlaps with an orthographic projection of the second connection line 80 on the base substrate.

FIG. 22 is a schematic diagram of a structure of a resistance compensation structure according to an exemplary embodiment of the present disclosure. On a side of the gate circuit region away from the display area, such as in the isolation dam region, the first sub-line and the second connection line in the lead group may be provided with a resistance compensation structure configured to reduce resistances of the first sub-line and the second connection line, and may adjust resistance differences caused by different connection line lengths in different lead groups.

As shown in FIG. 22, taking the second connection line 80 as an example, the resistance compensation structure 81 may be provided on a side of the second connection line 80 in the second direction Y, and both ends of the resistance compensation structure 81 are respectively connected to the second connection line 80.

In an exemplary embodiment, the resistance compensation structure 81 may be provided in the same layer as the second connection line 80, or may be provided in a different layer from the second connection line 80, and two ends of the resistance compensation structure 81 may be provided in a straight line shape, a polygonal line shape or a wavy shape, which is not limited in the present disclosure.

As can be seen from the structure and the preparing process of the display substrate described above, in the display substrate provided in the present disclosure, a base substrate conductive layer is provided between two flexible layers of the base substrate, the base substrate conductive layer includes a first connection line, and the first connection line is connected to a data signal line through a second connection line, thus data trace in the display area is achieved, which can reduce the width of the lower bezel, and is beneficial to achieving a full-screen display.

In a display substrate adopting a FIAA structure, a first lap via for connecting a first connection line to a second connection line is provided in an upper bezel region. The research shows that since the trace in this scheme is longer, the transmission path of the data signal is increased by 2 times, which not only results in a larger load, but also has a larger rising edge/falling edge of the data signal, thus it is not conducive to realizing a high refresh frequency. According to the display substrate provided by the exemplary embodiments of the present disclosure, by providing the first lap via, the second lap via, the first connection line and the second connection line on a side close to the bonding area, the present disclosure can effectively reduce the transmission path of the data signal, effectively reduce the load of the data signal, reduce the rising edge/falling edge (Tr/Tf) of the data signal, and facilitate the realization of a narrow bezel with a high refresh frequency, compared with providing the second lap via in the upper bezel region. In addition, in the present disclosure, the process quality of the opened first lap via can be effectively guaranteed by providing the first lap via outside the isolation dam. And a first lap via opened with a greater depth has less influence on the film layer structure of the display area, occupies less space and has a low production cost. The preparing processes in the present disclosure can be compatible well with existing preparing processes, which are simple in process implementation, easy to implement, high in production efficiency and yield, and low in production cost.

The structure shown and mentioned above in the present disclosure and the preparing process thereof are merely an exemplary description. In an exemplary embodiment, the corresponding structures may be altered and the patterning processes may be added or reduced according to actual needs. For example, the display substrate may include a shielding conductive layer. As another example, the second connection line may be provided in the shielding conductive layer or the first conductive layer. The present disclosure is not limited.

In an exemplary embodiment, the display substrate in the present disclosure may be applied to another display device having pixel drive circuits, such as a quantum dot display and the like, which is not limited in the present disclosure.

The present disclosure also provides a preparation method of a display substrate, for preparing the display substrate according to the foregoing embodiments. In an exemplary embodiment, the display substrate includes a display area, a side bezel region located on at least one side of the display area in the first direction, and a bonding area located on a side of the display area in the second direction, wherein the side bezel region at least includes a first bezel region and a second bezel region, the first bezel region is located on a side of the second bezel region close to the bonding area, and the first direction intersects the second direction. The preparation method may include: forming a base substrate including at least a first connection line; and forming a drive circuit layer on the base substrate, wherein the drive circuit layer at least includes a data signal line and a second connection line, the second connection line is connected to the first connection line through a first lap via, the data signal line is connected to the second connection line through a second lap via, and the first lap via is provided in the first bezel region.

The present disclosure also provides a display device including the aforementioned display substrate. The display device may be any product or component with a display function, such as a mobile phone, a tablet computer, a television, a display, a laptop computer, a digital photo frame, or a navigator, which is not limited in the present disclosure.

Although the implementations disclosed in the present disclosure are described as above, the described contents are only implementations which are used for facilitating the understanding of the present disclosure, but are not intended to limit the present invention. Any skilled person in the art to which the present disclosure pertains may make any modifications and variations in forms and details of implementations without departing from the spirit and scope of the present disclosure. However, the patent protection scope of the present invention should be subject to the scope defined by the appended claims.

1. A display substrate, comprising a display area, a side bezel region located on at least one side of the display area in a first direction, and a bonding area located on a side of the display area in a second direction, wherein the side bezel region at least comprises a first bezel region and a second bezel region, the first bezel region is located on a side of the second bezel region close to the bonding area, and the first direction intersects the second direction; the display substrate comprises a base substrate and a drive circuit layer provided on the base substrate, the base substrate at least comprises a first connection line, the drive circuit layer at least comprises a data signal line and a second connection line, the second connection line is connected to the first connection line through a first lap via, the data signal line is connected to the second connection line through a second lap via, and the first lap via is provided in the first bezel region.

2. The display substrate according to claim 1, wherein the display substrate comprises a first center line that is a straight line bisecting the display area in the second direction and extending in the first direction, the first bezel region is located on a side of the first center line close to the bonding area, and the first connection line and the second connection line are located on a side of the first center line close to the bonding area.

3. The display substrate according to claim 2, wherein the display substrate comprises a second center line that is a straight line bisecting the display area in the first direction and extending in the second direction; distances between a plurality of second lap vias and the second center line are gradually increased in a direction away from the first center line, and distances between the plurality of second lap vias and the first center line are gradually increased in a direction away from the second center line; or, distances between the plurality of second lap vias and the second center line are gradually reduced in a direction away from the first center line, and distances between the plurality of second lap vias and the first center line are gradually reduced in a direction away from the second center line.

4. The display substrate according to claim 1, wherein the bonding area at least comprises a lead line, a first end of the lead line is correspondingly connected to an integrated circuit in the bonding area, a second end of the lead line is correspondingly connected to a first end of the first connection line, a second end of the first connection line is connected to a first end of the second connection line through the first lap via after extending from the bonding area to the first bezel region through the display area, a second end of the second connection line is connected to the data signal line through the second lap via after extending from the first bezel region to the display area.

5. The display substrate according to claim 1, wherein the side bezel region comprises an encapsulation region and a non-encapsulation region that are divided by an encapsulation line, the encapsulation line is a boundary of an encapsulation structure layer covering the side bezel region, the encapsulation region is provided on a side of the encapsulation line close to the display area, the non-encapsulation region is provided on a side of the encapsulation line away from the display area, and the first lap via is provided in the non-encapsulation region.

6. The display substrate according to claim 1, wherein the drive circuit layer at least comprises a first conductive layer, a second conductive layer and a third conductive layer that are sequentially provided on the base substrate, the second connection line is provided in the first conductive layer or the second conductive layer, and the data signal line is provided in the third conductive layer.

7. The display substrate according to claim 1, wherein the first connection line comprises at least a first sub-line and a second sub-line, a first end of the second sub-line is connected to a lead line of the bonding area, a second end of the second sub-line is connected to a first end of the first sub-line after extending to the display area in the second direction, and a second end of the first sub-line is connected to a first end of the second connection line through the first lap via after extending to the first bezel region in the first direction.

8. The display substrate according to claim 7, wherein in the display area, for a first sub-line and a second connection line that transmit the same data signal, an orthographic projection of the first sub-line on the base substrate at least partially overlaps with an orthographic projection of the second connection line on the base substrate.

9. The display substrate according to claim 7, wherein in the second direction, extension lengths of a plurality of second connection lines are gradually increased or extension lengths of the second connection lines are gradually reduced.

10. The display substrate according to claim 7, wherein the drive circuit layer comprises circuit units constituting a plurality of unit rows and a plurality of unit columns, at least one circuit unit comprises a pixel drive circuit, at least one pixel drive circuit comprises a storage capacitor and a plurality of transistors, and orthographic projections of the first connection line and the second connection line on the base substrate do not overlap with orthographic projections of the storage capacitor and the plurality of transistors on the base substrate.

11. The display substrate according to claim 7, wherein the display substrate comprises a plurality of lead groups, at least one lead group comprises k first sub-lines, and k second connection lines correspondingly connected to the k first sub-lines through k first lap vias, the k second connection lines are correspondingly connected to k data signal lines through k second lap vias, and k is a positive integer greater than or equal to 1; and in the display area, at least one lead group is provided between adjacent unit rows.

12. The display substrate according to claim 11, wherein in the second direction, a distance between an i-th lead group and an (i+1)-th lead group is equal to a distance between the (i+1)-th lead group and an (i+2)-th lead group, i is a positive integer greater than or equal to 1, and less than or equal to N−2, and N is a quantity of the lead groups.

13. The display substrate according to claim 12, wherein k is 2, and a spacing between two second lap vias in the i-th lead group is equal to a spacing between two second lap vias in the (i+1)-th lead group.

14. The display substrate according to claim 11, wherein the side bezel region at least comprises a gate circuit region, the gate circuit region comprises a plurality of gate circuit groups sequentially provided in the second direction, a trace region is provided between adjacent gate circuit groups, and at least one lead group is provided in the trace region in the side bezel region; at least one gate circuit group comprises m scan gate circuits sequentially provided in the second direction and n light emitting gate circuits sequentially provided in the second direction, the n light emitting gate circuits are provided on a side of the m scan gate circuits away from the display area, m is a positive integer greater than or equal to 2, and n is a positive integer greater than or equal to 1.

15. The display substrate according to claim 14, wherein at least one scan gate circuit comprises a plurality of scan transistors and a scan storage capacitor, at least one light emitting gate circuit comprises a plurality of light emitting transistors and a light emitting storage capacitor, and in at least one lead group, orthographic projections of the first sub-line and the second connection line on the base substrate do not overlap with orthographic projections of the scan transistor, the scan storage capacitor, the light emitting transistor and the light emitting storage capacitor on the base substrate;
or
wherein the gate circuit region further comprises at least one start signal line and at least one clock signal line that extend in the second direction, and in at least one lead group, orthographic projections of the first sub-line and the second connection line on the base substrate have a first overlapping area with orthographic projections of the start signal line and the clock signal line on the base substrate.

16. (canceled)

17. The display substrate according to claim 15, wherein in the first overlapping area, an orthographic projection of the first sub-line on the base substrate does not overlap with an orthographic projection of the second connection line on the base substrate.

18. The display substrate according to claim 17, wherein in a side bezel region other than the first overlapping area, for a first sub-line and a second connection line that transmit the same data signal, an orthographic projection of the first sub-line on the base substrate at least partially overlaps with an orthographic projection of the second connection line on the base substrate.

19. The display substrate according to claim 11, wherein at least one first sub-line or at least one second connection line is provided with a resistance compensation structure provided on a side of the gate circuit region away from the display area.

20. A display device, comprising a display substrate according to claim 1.

21. A method for preparing a display substrate, wherein the display substrate comprises a display area, a side bezel region located on at least one side of the display area in a first direction, and a bonding area located on a side of the display area in a second direction, wherein the side bezel region at least comprises a first bezel region and a second bezel region, the first bezel region is located on a side of the second bezel region close to the bonding area, and the first direction intersects the second direction; and the method comprises:
forming a base substrate at least comprising a first connection line; and
forming a drive circuit layer on the base substrate, wherein the drive circuit layer at least comprises a data signal line and a second connection line, the second connection line is connected to the first connection line through a first lap via, the data signal line is connected to the second connection line through a second lap via, and the first lap via is provided in the first bezel region.
